(19) United States
(12) Patent Application Publication
(10) Pub. No.: US 2008/0211001 A1
(43) Pub. Date: Sep. 4, 2008

(54) SEMICONDUCTOR DEVICE AND A METHOD OF MANUFACTURING THE SAME

(76) Inventors: Kazuyoshi Shiba, Tokyo (JP); Hideyuki Yashima, Tokyo (JP); Yasushi Oka, Tokyo (JP)

Correspondence Address: MILES & STOCKBRIDGE PC, 1751 PINNACLE DRIVE, SUITE 500, MCLEAN, VA, 22102-3833, US

(21) Appl. No.: 12/013,470

(22) Filed: Jan. 13, 2008

(30) Foreign Application Priority Data
Mar. 2, 2007 (JP) 2007-052529

(51) Int. Cl. H01L 27/06; H01L 21/28

(52) U.S. Cl. 257/298; 257/316; 438/591; 257/E27.014; 257/E21.179

(57) ABSTRACT

Provided is a semiconductor device having, over the main surface of a semiconductor substrate, a main circuit region and a memory cell array of a flash memory. The memory cell array has a floating gate electrode for accumulating charges of data, while the main circuit region has a gate electrode of MIS•FET constituting the main circuit. In the main circuit region, an insulating film made of a silicon nitride film is formed to cover the gate electrode, whereby miniaturization of elements in the main circuit region is not impaired. The memory cell array has no such insulating film. This means that the upper surface of the floating gate electrode is not contiguous to the insulating film but is covered directly with an interlayer insulating film. According to such a constitution, leakage of electrons from the floating gate electrode of the memory cell array can be suppressed or prevented and the flash memory thus obtained has improved data retention characteristics.

### CROSS-REFERENCE TO RELATED APPLICATIONS

The disclosure of Japanese Patent Application No. 2007-52529 filed on Mar. 2, 2007 including the specification, drawings and abstract is incorporated herein by reference in its entirety.

### BACKGROUND OF THE INVENTION

The present invention relates to a semiconductor device and a manufacturing technology thereof, in particular, to a technology effective when applied to a semiconductor device having a nonvolatile memory.

Some semiconductor devices have, therein, a nonvolatile memory circuit portion for storing data to be used, for example, during trimming, data rescue or image adjustment of LCD (Liquid Crystal Device) or data of a relatively small capacity such as production number of the semiconductor devices.

A semiconductor device having such a nonvolatile memory circuit portion is described, for example, in Japanese Patent Laid-Open No. 2001-185633 (Patent Document 1). This document discloses a single level-poly-EEPROM device which is an EEPROM (Electric Erasable Programmable Read Only Memory) device formed over a single conductive layer placed over a semiconductor substrate while being isolated therefrom via an insulating film and whose area per bit can be reduced.

Japanese Patent Laid-Open No. 2001-257324 (Patent Document 2) discloses a technology capable of improving the long-term data retention capacity of a nonvolatile memory device formed by a single-layer poly-flash technology.

For example, in FIG. 7 of U.S. Pat. No. 6,788,574 (Patent Document 3), disclosed is a structure having a capacitor portion, a program transistor and a readout transistor, each isolated by an n well. In columns 6 and 7 of FIGS. 4A to 4C of Patent Document 3, disclosed is a structure in which program/erase is performed by means of an FN tunneling current.

For example, the structure disclosed in FIG. 1 of Japanese Patent Laid-Open No. 2000-311992 (Patent Document 4) and description thereon has a first insulating film made of a silicon nitride film in a memory cell region in which a memory cell having a two-layer gate electrode has been placed but does not have an insulating film made of a silicon nitride film in a peripheral circuit region.

For example, in paragraphs 0065 to 0067 and FIG. 8 of Japanese Patent Laid-Open No. 2000-183313 (Patent Document 5), disclosed is a technology of depositing a silicon nitride film over a semiconductor substrate and forming a sidewall spacer on the side surfaces of a gate electrode by covering, with a resist film, the silicon nitride film of a memory array region in which a memory cell having a two-layer gate electrode has been placed and removing the silicon nitride film from a logic LSI formation region by etching.

### SUMMARY OF THE INVENTION

There is an L-SAC (Self Aligned Contact Hole) technology for forming contact holes of a semiconductor device.

In this technology, a silicon nitride film functioning as an etching stopper is formed in advance between an interlayer insulating film made of a silicon oxide film and a semiconductor substrate so as to cover a gate electrode or underlying interconnect and a large etch selectivity is ensured between the silicon oxide film and silicon nitride film during formation of the contact hole in the interlayer insulating film. This makes it possible to improve the size or margin for misalignment in a lithography step for forming the contact hole in the interlayer insulating film.

In the case where the L-SAC technology is employed in the above-described semiconductor device having a nonvolatile memory, the silicon nitride film serving as an etching stopper may deteriorate the data retention characteristics of the nonvolatile memory when it is deposited over the semiconductor substrate while being in a direct contact with the floating gate electrode of the nonvolatile memory.

The above-described problem occurs because of the following reason. When the silicon nitride film is deposited by plasma chemical vapor deposition (CVD), the silicon nitride film tends to be a silicon-rich film in the initial stage of deposition. Owing to the silicon nitride film in direct contact with the upper surface of the floating gate electrode, charges in the floating gate electrode flow toward the semiconductor substrate via a silicon-rich portion of the silicon nitride film and released via a plug in the contact hole.

An object of the present invention is to provide a technology capable of improving the reliability of a semiconductor device, in particular, a technology capable of improving the data retention characteristics of a nonvolatile memory.

The above-described and other objects and novel features of the present invention will be apparent by the description herein and accompanying drawings.

Outline of the typical invention, of the inventions disclosed by the present invention, will hereinafter be described.

In the present invention, there is thus provided a semiconductor device having a first circuit region having a nonvolatile memory and a second circuit region having a circuit other than the nonvolatile memory, wherein in the second circuit region, a nitrogen-containing insulating film is formed between a semiconductor substrate and an oxygen-containing insulating film formed over the first main surface thereof and in the first circuit region, a nitrogen-containing insulating film is not formed between the oxygen-containing insulating film and the first main surface of the semiconductor substrate.

Advantages available by the typical invention, among the inventions disclosed by the present application, will next be described briefly.

The present invention makes it possible to provide a semiconductor device having improved reliability, in particular, a nonvolatile memory having improved data retention characteristics.

### BRIEF DESCRIPTION OF THE DRAWINGS

FIG. 1 is a fragmentary cross-sectional view of a semiconductor device having a nonvolatile memory which is investigated by the present inventors;

FIG. 2 is a fragmentary cross-sectional view of another constitution of a semiconductor integrated circuit device having a nonvolatile memory which is investigated by the present inventors;

FIG. 3 is a fragmentary cross-sectional view of a semiconductor device according to one embodiment of the present invention;

FIG. 4 is a fragmentary cross-sectional view of a semiconductor device according to another embodiment of the present invention;

FIG. 5 is a graph showing the comparison of data retention characteristics of the nonvolatile memories of the semiconductor devices in FIGS. 1 to 4;

FIG. 6 is a fragmentary circuit diagram of a nonvolatile memory cell in the semiconductor device according to the one embodiment of the present invention;

FIG. 7 is a circuit diagram showing a voltage applied to each portion of the nonvolatile memory of FIG. 6 at the time of data program operation;

FIG. 8 is a circuit diagram showing a voltage applied to each portion of the nonvolatile memory of FIG. 6 at the time of data batch erase operation;

FIG. 9 is a circuit diagram showing a voltage applied to each portion of the nonvolatile memory of FIG. 6 at the time of data bit-wise erase operation;

FIG. 10 is a circuit diagram showing a voltage applied to each portion of the nonvolatile memory of FIG. 6 at the time of data read operation;

FIG. 11 is a plan view of a memory cell, corresponding to one bit, of the nonvolatile memory in the semiconductor device according to the one embodiment of the present invention;

FIG. 12 is a cross-sectional view taken along a line Y2-Y2 of FIG. 11;

FIG. 13 is a fragmentary cross-sectional view of a main circuit region in the semiconductor device according to the one embodiment of the present invention;

FIG. 14 is a cross-sectional view taken along a line Y2-Y2 of FIG. 11 and illustrates one example of a voltage applied to each portion, at the time of data program operation, of a memory cell of the nonvolatile memory in the semiconductor device according to the one embodiment of the present invention;

FIG. 15 is a cross-sectional view taken along a line Y2-Y2 of FIG. 11 and illustrates a voltage applied to each portion, at the time of data erase operation, of the nonvolatile memory in the semiconductor device according to the one embodiment of the present invention;

FIG. 16 is a cross-sectional view taken along a line Y2-Y2 of FIG. 11 and illustrates a voltage applied to each portion, at the time of data read operation, of the nonvolatile memory in the semiconductor device according to the one embodiment of the present invention;

FIG. 17 is a fragmentary cross-sectional view of a semiconductor substrate in a main circuit formation region during a manufacturing step of a semiconductor device according to another embodiment of the present invention;

FIG. 18 is a fragmentary cross-sectional view of a semiconductor substrate in a nonvolatile memory region in the same step as that of FIG. 17;

FIG. 19 is a fragmentary cross-sectional view of a semiconductor substrate in the main circuit formation region during a manufacturing step of the semiconductor device following the step of FIG. 17 and FIG. 18;

FIG. 20 is a fragmentary cross-sectional view of a semiconductor substrate in the nonvolatile memory region in the same step as that of FIG. 19;

FIG. 21 is a fragmentary cross-sectional view of a semiconductor substrate in the main circuit formation region during a manufacturing step of the semiconductor device following the step of FIG. 19 and FIG. 20;

FIG. 22 is a fragmentary cross-sectional view of a semiconductor substrate in the nonvolatile memory region in the same step as that of FIG. 21;

FIG. 23 is a fragmentary cross-sectional view of a semiconductor substrate in the main circuit formation region during a manufacturing step of the semiconductor device following the step of FIG. 21 and FIG. 22;

FIG. 24 is a fragmentary cross-sectional view of a semiconductor substrate in the nonvolatile memory region in the same step as that of FIG. 23;

FIG. 25 is a fragmentary cross-sectional view of a semiconductor substrate in the main circuit formation region during a manufacturing step of the semiconductor device following the step of FIG. 23 and FIG. 24;

FIG. 26 is a fragmentary cross-sectional view of a semiconductor substrate in the nonvolatile memory region in the same step as that of FIG. 25;

FIG. 27 is a fragmentary cross-sectional view of a semiconductor substrate in the main circuit formation region during a manufacturing step of the semiconductor device following the step of FIG. 25 and FIG. 26;

FIG. 28 is a fragmentary cross-sectional view of a semiconductor substrate in the nonvolatile memory region in the same step as that of FIG. 27;

FIG. 29 is a fragmentary cross-sectional view of a semiconductor substrate in the main circuit formation region during a manufacturing step of the semiconductor device following the step of FIG. 27 and FIG. 28;

FIG. 30 is a fragmentary cross-sectional view of a semiconductor substrate in the nonvolatile memory region in the same step as that of FIG. 29;

FIG. 31 is a fragmentary cross-sectional view of a semiconductor substrate in the main circuit formation region during a manufacturing step of the semiconductor device following the step of FIG. 29 and FIG. 30;

FIG. 32 is a fragmentary cross-sectional view of a semiconductor substrate in the nonvolatile memory region in the same step as that of FIG. 31;

FIG. 33 is a plan view illustrating one example of a memory cell of a nonvolatile memory in a semiconductor device according to a further embodiment of the present invention (Embodiment 2);

FIG. 34 is a cross-sectional view taken along a line Y3-Y3 of FIG. 33;

FIG. 35 is a fragmentary cross-sectional view of a main circuit region of the semiconductor device according to the further embodiment (Embodiment 2) of the present invention;

FIG. 36 is a cross-sectional view taken along a line Y2-Y2 of FIG. 11 and illustrates one example of a memory cell of a nonvolatile memory in a semiconductor device according to a still further embodiment (Embodiment 3) of the present invention;

FIG. 37 is a fragmentary cross-sectional view of a main circuit region of the semiconductor device according to the still further embodiment (Embodiment 3) of the present invention;

FIG. 38 is a fragmentary plan view of a nonvolatile memory region in a semiconductor device according to a still further embodiment (Embodiment 4) of the present invention;

FIG. 39 is a plan view of a nonvolatile memory region in a semiconductor device according to a still further embodiment (Embodiment 5) of the present invention; and

FIG. 40 is a plan view of a nonvolatile memory region in a semiconductor device according to a still further embodiment (Embodiment 6) of the present invention.

### DETAILED DESCRIPTION OF THE PREFERRED EMBODIMENTS

In the below-described embodiments, a description will be made after divided in plural sections or in plural embodiments if necessary for convenience's sake. These plural sections or embodiments are not independent each other, but in a relation such that one is a modification example, details or complementary description of a part or whole of the other one unless otherwise specifically indicated. In the below-described embodiments, when a reference is made to the number of elements (including the number, value, amount and range), the number of elements is not limited to a specific number but can be greater than or less than the specific number unless otherwise specifically indicated or in the case it is principally apparent that the number is limited to the specific number. Moreover in the below-described embodiments, it is needless to say that the constituting elements (including element steps) are not always essential unless otherwise specifically indicated or in the case where it is principally apparent that they are essential. Similarly, in the below-described embodiments, when a reference is made to the shape or positional relationship of the constituting elements, that substantially analogous or similar to it is also embraced unless otherwise specifically indicated or in the case where it is utterly different in principle. This also applies to the above-described value and range. In all the drawings for describing the below-described embodiments, elements having like function will be identified by like reference numerals and overlapping descriptions will be omitted as much as possible. Embodiments of the present invention will next be described in detail based on accompanying drawings.

### Embodiment 1

A first description will be made of the problem of a semiconductor device having a flash memory as a nonvolatile memory which device is the subject of the investigation by the present inventors.

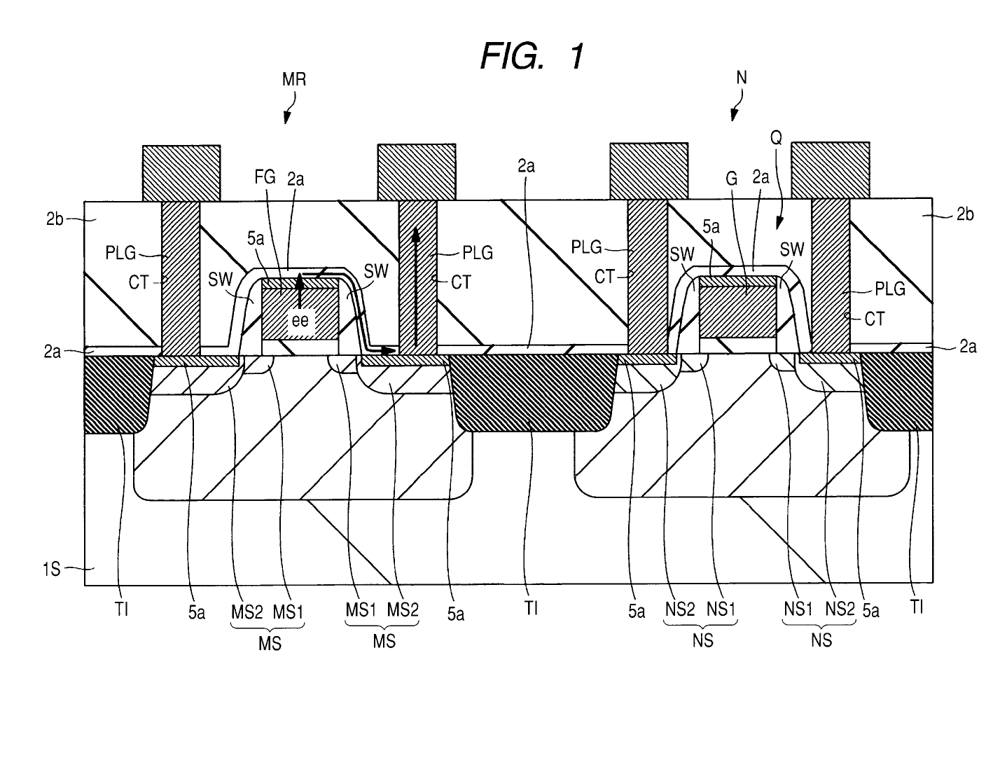

FIG. 1 is a fragmentary cross-sectional view of a semiconductor device having a flash memory which is investigated by the present inventors. In this drawing, symbol “MR” represents a memory cell array (first circuit region) of the flash memory and symbol “N” represents a main circuit region (second circuit region). Here, the main circuit region N is shown as an example of the second circuit region. The term “second circuit region” as used herein embraces, as well as the main circuit region N, regions in which circuits other than the flash memory are to be arranged, for example, a region in which a peripheral circuit of the flash memory is to be arranged.

A semiconductor substrate (which will hereinafter be called “substrate” simply) 1S constituting a semiconductor chip is made of, for example, p type (second conductivity type) silicon (Si) single crystals. This substrate 1S has a main surface (first main surface) and a backside surface (second main surface) which are opposite to each other along the thickness direction of the substrate. The substrate 1S has, in the main surface thereof, an isolation portion TI. This isolation portion TI defines an active region. In this embodiment, the isolation portion TI is a trench type isolation portion so-called SGI (Shallow Groove Isolation) or STI (Shallow Trench Isolation) formed by filling an insulating film made of, for example, a silicon oxide film in a shallow trench made in the main surface of the substrate 1S.

A floating gate electrode FG of the memory cell array MR is a charge accumulating portion which contributes to the storage of data. This floating gate electrode FG is made of, for example, a conductor film such as low-resistance polycrystalline silicon and is in the electrically floating state (insulated from another conductor).

Semiconductor regions MS are formed in the substrate 1S (on both sides with a channel therebetween) on the right and left sides of the width direction of the floating gate electrode FG of the memory cell array. These semiconductor regions MS each has a lightly doped semiconductor region MS1 and a heavily doped semiconductor region MS2 having a higher impurity concentration than the lightly doped semiconductor region.

The lightly doped semiconductor region MS1 is formed at a position closer to the channel than the heavily doped semiconductor region MS2. The lightly doped semiconductor region MS1 and heavily doped semiconductor region MS2 have the same conductivity type and they are electrically connected to each other.

A gate electrode G of the main circuit region N is a gate electrode of MIS•FET Q for the formation of the main circuit. This gate electrode G is made of, for example, a conductor film such as low resistance polycrystalline silicon film.

Semiconductor regions NS are formed in the substrate 1S (on both sides with a channel therebetween) on the right and left sides of the width direction of the gate electrode G of the main circuit region N. These semiconductor regions NS each has a lightly doped semiconductor region NS1 and a heavily doped semiconductor region NS2 having a higher impurity concentration than the lightly doped semiconductor region NS1.

The lightly doped semiconductor region NS1 is formed at a position closer to the channel than the heavily doped semiconductor region NS2. The lightly doped semiconductor region NS1 and heavily doped semiconductor region NS2 have the same conductivity type and they are electrically connected to each other.

An insulating film 2a is deposited over the main surface of the substrate 1S to cover the floating gate electrode FG and gate electrode G. Over the insulating film 2a, an interlayer insulating film (insulating film) 2b which is thicker than the underlying insulating film 2a is deposited.

The insulating film 2a is made of, for example, a silicon nitride film, while the interlayer insulating film 2b is made of, for example, a silicon oxide film. The insulating film 2a and the interlayer insulating film 2b are made of respective materials capable of ensuring a large etch selectivity therebetween during etching. Described specifically, the underlying insulating film 2a is an insulating film for L-SAC (Self Aligned Contact) and it functions as an etching stopper during etching for the formation of contact holes CT. Formation of the insulating film 2a enables size reduction of elements in the main circuit region N.

A silicide layer 5a such as cobalt silicide (CoSi₂) is formed on the upper surfaces of the floating gate electrode FG and gate electrode G and upper surfaces of the heavily doped semiconductor regions MS2 and NS2. On the side surfaces of the floating gate electrode FG and gate electrode G, a sidewall SW made of, for example, a silicon oxide film is formed.

According to the constitution investigated by the present inventors, the insulating film 2a is in direct contact with the upper surface of the floating gate electrode FG. Direct contact of the insulating film 2a with the floating gate electrode FG may deteriorate the data retention characteristics of the flash memory. This problem may occur because the insulating film 2a deposited by plasma CVD or the like tends to be a silicon-rich film in the initial stage of deposition so that when the insulating film 2a is in direct contact with the upper surface of the floating gate electrode FG, charges e in the floating gate electrode FG flow toward the substrate 1S via the silicon-rich portion of the insulating film 2a as shown by an arrow and are released via a plug PLG in the contact hole CT.

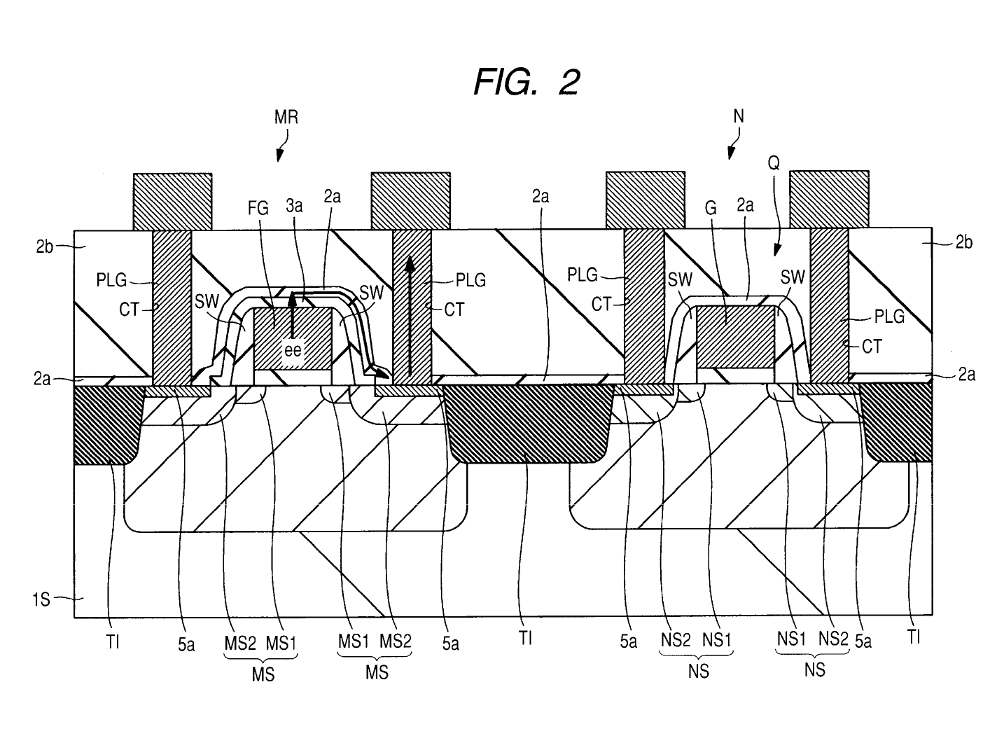

FIG. 2 is a fragmentary cross-sectional view of another constitution of a semiconductor device having a flash memory which was investigated by the present inventors. A difference from the constitution illustrated in FIG. 1 is that a cap insulating film (insulating film) 3a made of, for example, a silicon oxide film is formed between the floating gate electrode FG and insulating film 2a and the floating gate electrode FG has no silicide layer 5a formed thereon. In this constitution, the flash memory has improved data retention characteristics compared with the above-described constitution of FIG. 1, but owing to release of a charge e of the floating gate electrode FG via the insulating film 2a, the problem of deterioration of data retention characteristics of the flash memory still remains unsolved.

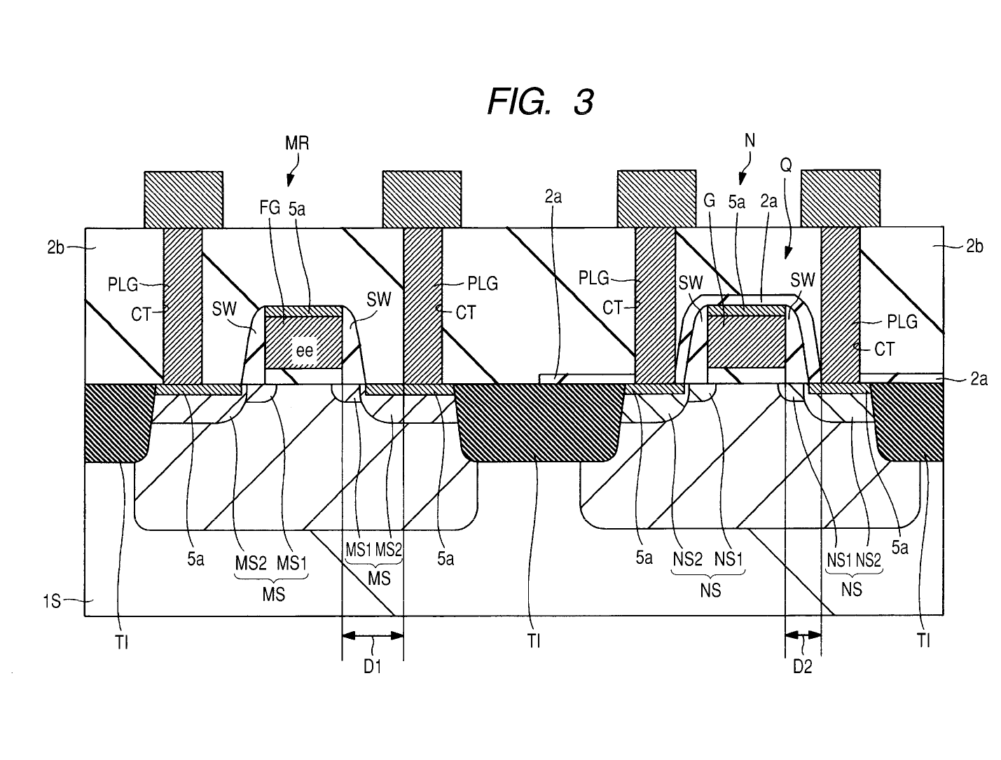

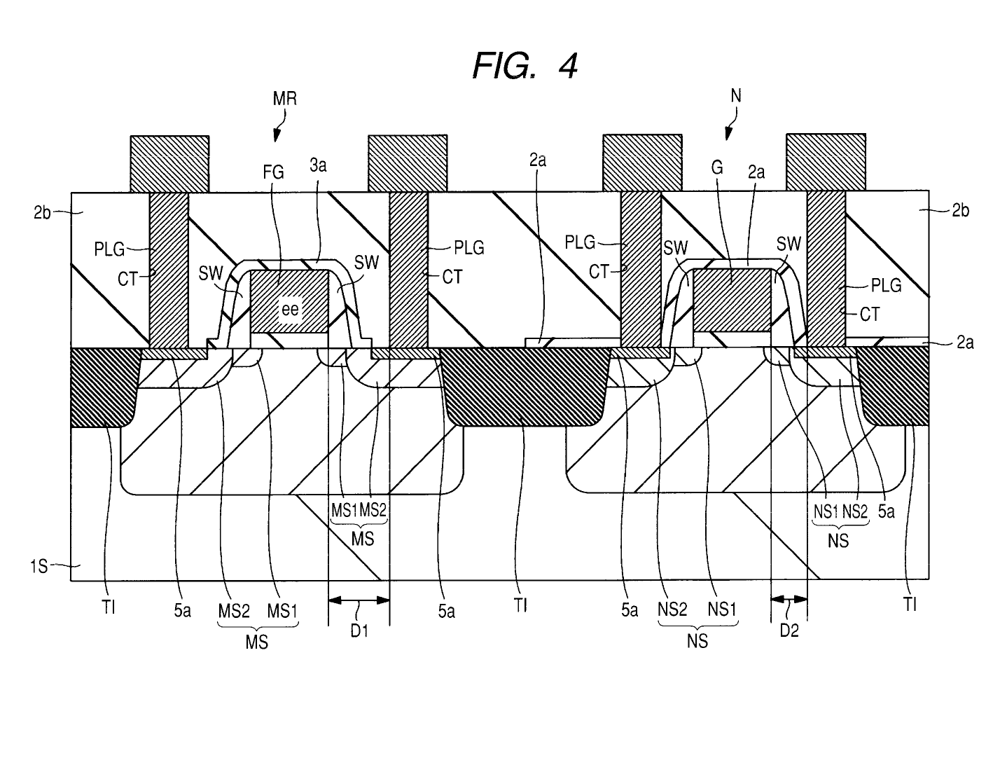

In the semiconductor device of Embodiment 1, therefore, a nitrogen-containing insulating film 2a is formed in the main circuit region N but the nitrogen-containing insulating film 2a is not formed in the memory cell array MR of the flash memory as illustrated in FIGS. 3 and 4.

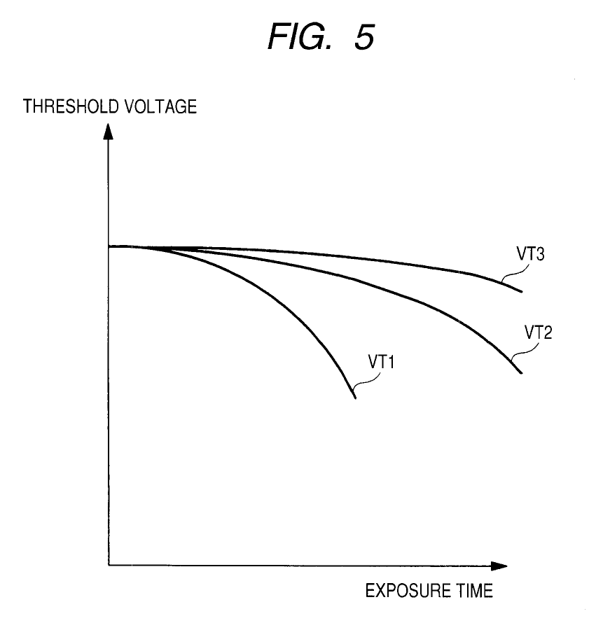

FIG. 3 illustrates the constitution of FIG. 1 in which the insulating film 2a is not formed in the memory cell array MR, while FIG. 4 illustrates the constitution of FIG. 2 in which the insulating film 2a is not formed in the memory cell array MR. FIG. 5 is a graph showing comparison of the data retention characteristics of the flash memory among the constitutions of FIGS. 1 and 2 and the constitution of Embodiment 1. In FIG. 5, symbol VT1 represents data retention characteristics of the constitution of FIG. 1, symbol VT2 represents those of the constitution of FIG. 2, and symbol VT3 represents those of FIGS. 3 and 4.

In the constitutions of FIGS. 3 and 4, miniaturization is not impaired because the insulating film 2a is formed in the main circuit region N. Since no insulating film 2a is formed in the memory cell array MR in the constitutions of FIGS. 3 and 4 (symbol VT3), leakage of a charge e from the floating gate electrode FG can be made smaller than that of the constitutions of FIGS. 1 and 2 (symbols VT1 and VT2). The flash memory can therefore have improved data retention characteristics.

As illustrated in FIGS. 3 and 4, a distance D1 from the side surface of the floating gate electrode FG of the memory cell array MR to a plug PLG opposite thereto is longer than a distance D2 from the side surface of the gate electrode G of the main circuit region N to the plug PLG opposite thereto. This means that the semiconductor region MS on the memory array MR side is wider, in the gate length direction, than the semiconductor region NS of the main circuit region N. Even without the insulating film 2a in the memory cell array MR, no problem relating to the miniaturization of the memory cell array MR occurs.

According to the constitution of FIG. 4, the cap insulating film 3a formed to cover therewith the upper surface of the floating gate electrode FG functions to protect the upper surface of the floating gate electrode FG during removal of the insulating film 2a by etching from the memory cell array MR. This makes it possible to improve the production yield and reliability of the semiconductor device.

Moreover, according to the constitution of FIG. 4, the cap insulating film 3a covers therewith the upper surface of the floating gate electrode FG and the surface of the sidewall SW on the side surface of the floating gate electrode FG and also a portion of the main surface of the substrate 1S. This means that the silicide layer 5a is formed in alignment with the cap insulating film 3a, whereby an end portion of the silicide layer 5a formed on the main surface of the substrate 1S can be separated from the side surface of the floating gate electrode FG, that is, the lightly doped semiconductor region MS1. Growth of the silicide layer 5a into the lightly doped semiconductor region MS1 increases the occurrence possibility of a junction leakage current between the silicide layer 5a and the substrate 1S. In particular, when the lightly doped semiconductor region MS1 and the lightly-doped semiconductor region of a low-breakdown-voltage MIS•FET in the main circuit region are formed by the same step (at the same impurity concentration), the occurrence possibility of the above-described problem increases.

In Embodiment 1, on the other hand, the end portion of the silicide layer 5a formed on the main surface of the substrate 1S can be spaced from the lightly doped semiconductor region MS1 so that occurrence of junction leakage between the silicide layer 5a and the substrate 1S can be suppressed or prevented.

A specific example of the semiconductor device according to Embodiment 1 will hereinafter be described.

A semiconductor chip constituting the semiconductor device of Embodiment 1 has therein a main circuit region (second circuit region) and a region of a flash memory (nonvolatile memory, first circuit region) for storing desired data of a relatively small capacity relating to the main circuit.

The main circuit is, for example, a memory circuit such as DRAM (Dynamic Random Access Memory) or SRAM (Static RAM). In addition, the main circuit is, for example, a logic circuit such as CPU (Central Processing Unit) or MPU (Micro Processing Unit). The main circuit is, in addition, a mixed circuit of the memory circuit and logic circuit, an LCD (Liquid Crystal Device) driver circuit, or the like.

The desired data include, for example, location address information of an effective (usable) element to be used for trimming in a semiconductor chip, location address information of an effective memory cell (defect-free memory cell) or effective LCD to be used for rescue of a memory or LCD, trimming tap information of a control voltage to be used for adjustment of an LCD image, and a product number of a semiconductor device.

Such a semiconductor device (semiconductor chip, semiconductor substrate) uses, as an outside power source, a single power source. The supply voltage of the single power source is, for example, about 3.3V.

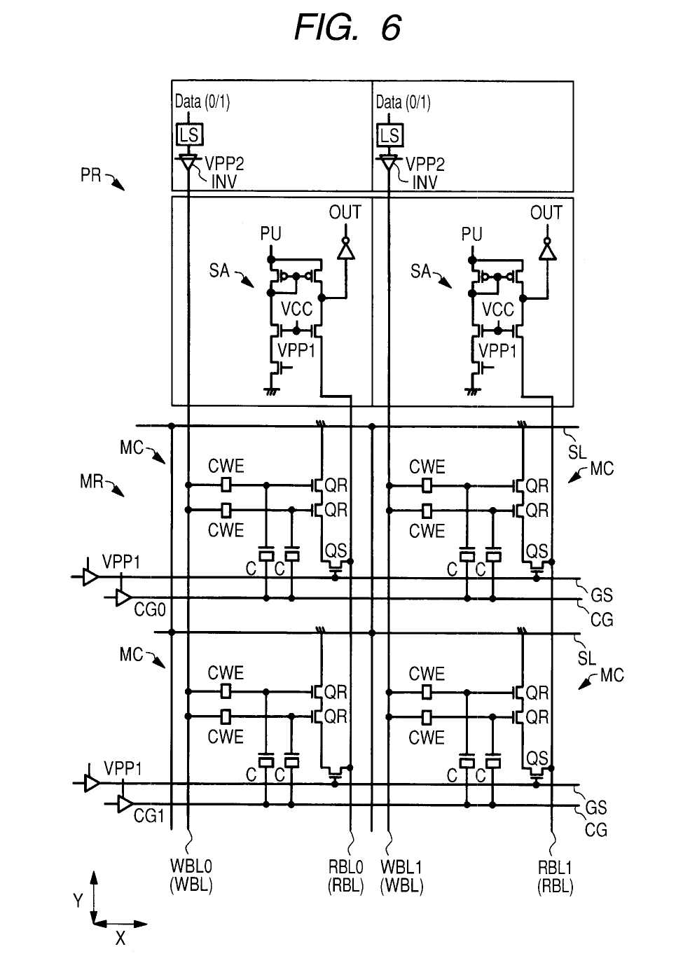

FIG. 6 is a fragmentary circuit diagram of the flash memory in the semiconductor device according to Embodiment 1. This flash memory has a memory cell array MR and a peripheral circuit region PR. In the memory cell array MR, a plurality of bit lines WBL (WBL0, WBL1 . . . ) for programming•erasing data and a plurality of bit lines RBL (RBL0, RBL2 . . . ) for reading data, each extending in the first direction Y, are arranged along the second direction X. Moreover, in the memory cell array MR, a plurality of control gate lines (word lines) CG (CG0, CG1 . . . ), a plurality of source lines SL and a plurality of select lines GS, each extending along the second direction X which is perpendicular to the bit lines WBL and RBL, are arranged along the first direction Y.

The bit lines WBL for programming•erasing data are each electrically connected to an inverter circuit INV for inputting data (0/1) which is placed in the peripheral circuit region PR. The bit lines RBL for reading data are each electrically connected to a sense amplifier circuit SA placed in the peripheral circuit region PR. The sense amplifier circuit SA is, for example, a current mirror type circuit. To the vicinity of the intersections on the matrix formed by the bit lines WBL and RBL and the control gate line CG, source line SL and select line GS, memory cells equivalent to one bit are connected. In this diagram, one bit is formed by two memory cells MC.

The memory cells MC each has a capacitor portion (charge injection/emission portion) CWE for programming•erasing data, MIS•FET QR for reading data, a capacitor portion C and a select MIS•FET QS. The data program•erase capacitor portions CWE and CWE of each of the two memory cells MC constituting one bit are electrically connected so that they are in parallel with each other. One of the electrodes of each of the data program•erase capacitor portions CWE is electrically connected to the data program•erase bit line WBL, while the other electrodes (floating gate electrodes FG) of the data program•erase capacitor portions CWE are electrically connected to the gate electrodes (floating gate electrodes FG) of the data read MIS•FET QR and QR, respectively and at the same time, electrically connected to the respective electrodes (floating gate electrodes FG) of the capacitor portions C and C. The other electrodes (floating gate electrodes CGW) of the capacitor portions C and C are electrically connected to the control gate line CG. The data read MIS•FET QR and QR of the two memory cells MC constituting one bit are electrically connected with each other in series. Their drain is electrically connected to a data read bit line RBL via the select MIS•FET QS and the source is electrically connected to the source line SL. The gate electrode of the select MIS•FET QS is electrically connected to the select line GS.

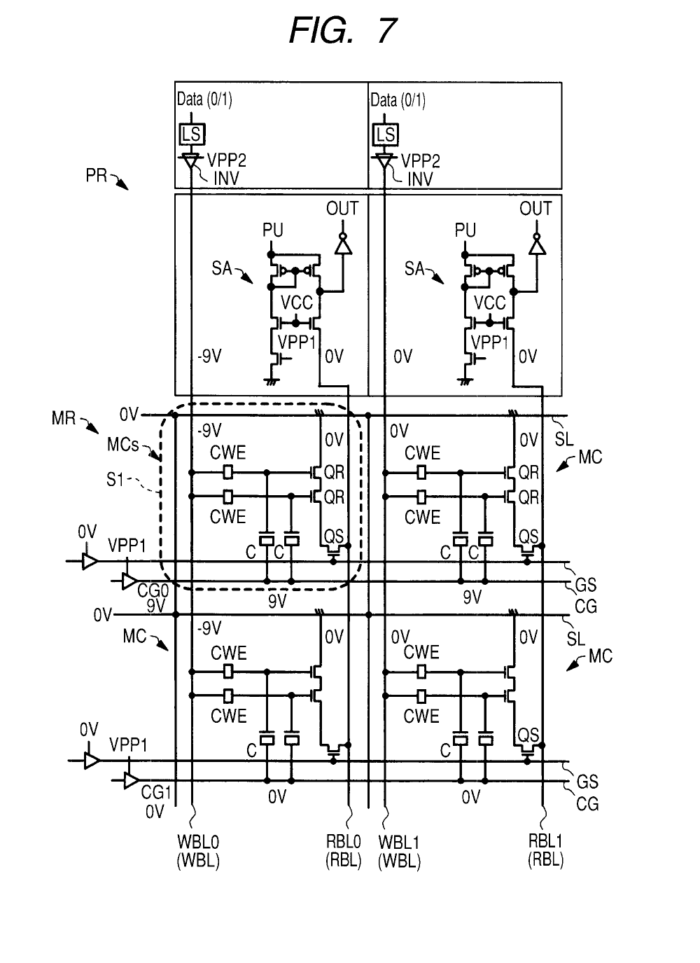

An example of data program operation in such a flash memory will next be described based on FIGS. 7 to 10. FIG. 7 shows a voltage applied to each portion of the flash memory of FIG. 6 at the time of data program operation. A dashed line S1 indicates a memory cell MC (which will hereinafter be called “selected memory cell MCs”) in which data are programmed. Here, injection of electrons into a floating gate electrode is defined as programming of data. On the contrary, it is also possible to define the ejection of electrons from the floating gate electrode as “programming of data”.

At the time of data programming, a positive control voltage, for example, about 9V is applied to the control gate line CG0 (CG) to which the other electrode of the capacitor portion C of the selected memory cell MCs is connected. A voltage of about 0V is applied to the other control gate line CG1 (CG). In addition, a negative voltage, for example, about −9V is applied to the bit line WBL0 (WBL) for programming•erasing data to which one of the electrodes of the data program•erase capacitor portion CWE of the selected memory cell MCs is connected. A voltage of, for example, about 0V is applied to the other bit line WBL1 (WBL) for programming•erasing data. A voltage of, for example, 0V is applied to the select line GS, source line SL and data read bit line RBL. By these operations, electrons are injected into the floating gate electrodes of the data program•erase capacitor portions CWE and CWE of the selected memory cell MCs by means of an FN tunneling current of an entire channel surface, whereby data programming is performed.

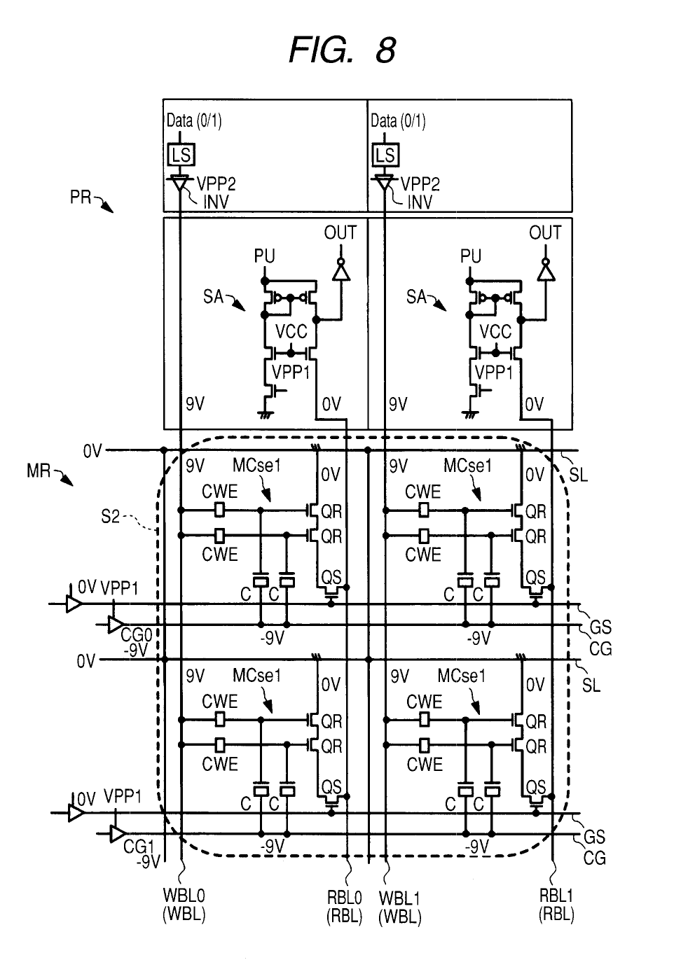

FIG. 8 shows a voltage applied to each portion of the flash memory of FIG. 6 at the time of data batch erase operation. A dashed line S2 indicates a plurality of memory cells (MC) (which will hereinafter be called “selected memory cells MCse1”) to be subjected to data batch erasing. Here, ejection of electrons from the floating gate electrode is defined as “data erasing”. On the contrary, injection of electrons into the floating gate electrode can also be defined as “data erasing”.

When the batch data erasing is carried out, a negative control voltage of, for example, about −9V is applied to the control gate lines CG0 and CG1 (CG) to which the other electrode of the capacitor portion C of the plural selected memory cells MCse1 is connected. A positive voltage of, for example, about 9V is applied to the data program•erase bit lines WBL0 and WBL1 (WBL) to which one of the electrodes of the data program•erase capacitor portion CWE of the selected memory cell MCse1 is connected. A voltage of, for example, 0V is applied to the select line GS, source line SL and data read bit line RBL. By these operations, electrons accumulated in the floating gate electrodes of the data program•erase capacitor portions CWE and CWE of the plural selected memory cells MCse1 to be subjected to data batch erasing are emitted by means of an FN tunneling current of an entire channel surface, whereby batch data erasing from the plural selected memory cells MCse1 is completed.

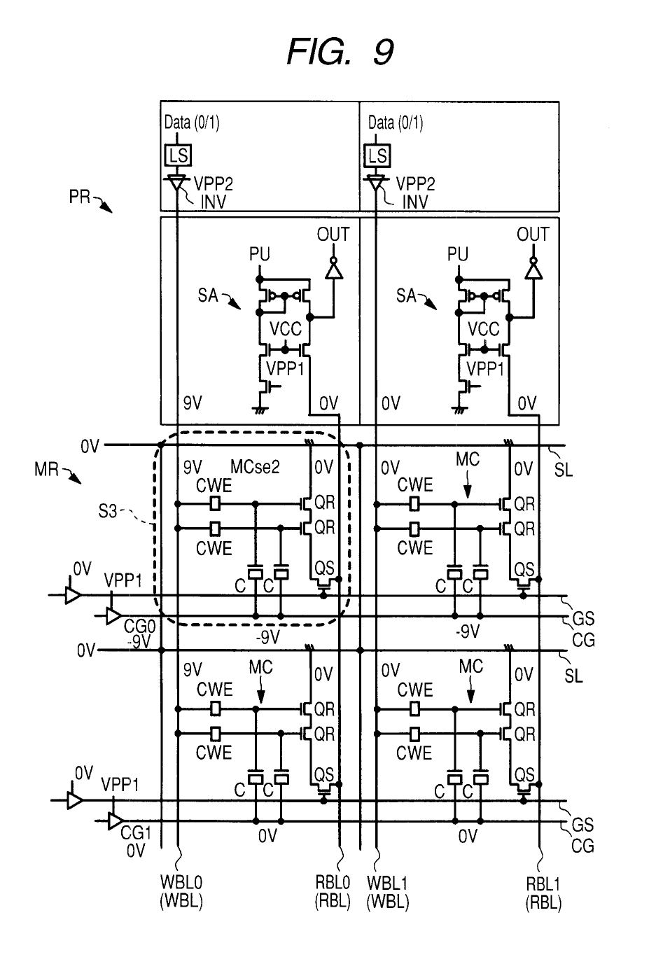

FIG. 9 shows a voltage applied to each portion of the flash memory of FIG. 6 at the time of data bit-wise erase operation. The dashed line S3 indicates a memory cell MC (which will hereinafter be called “selected memory cell MCse2”) from which data are erased bit by bit.

At the time of bit-wise data erasing, a negative control voltage of, for example, about −9V is applied to the control gate line CG0 (CG) to which the other electrode of the capacitor portion C of the selected memory cell MCse2 is connected. To the other control gate line CG1 (CG) is applied a voltage of, for example, 0V. To the data program•erase bit line WBL0 (WBL) to which one of the electrodes of the data program•erase capacitor portion CWE of the selected memory cell MCse2 is connected is applied a positive voltage of, for example, about 9V. To the other data program•erase bit line WBL1 (WBL) is applied a voltage of, for example, 0V. To the select line GS, source line SL and data read bit line RBL is applied, for example, 0V. By these operations, electrons accumulated in the floating gate electrodes of the data program•erase capacitor portions CWE and CWE of the selected memory cell MCse2 to be subjected to data erasing are emitted by means of an FN tunneling current of an entire channel surface, whereby data are erased from the selected memory cell MCse2 to be subjected to data erasing.

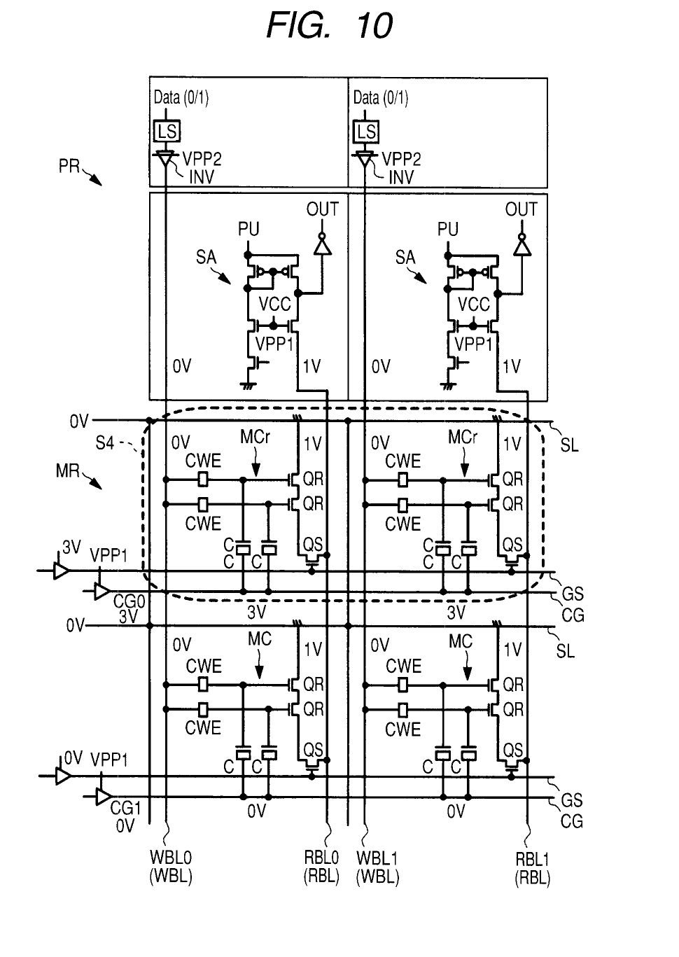

FIG. 10 is a voltage applied to each portion of the flash memory of FIG. 6 at the time of data read operation. A dashed line S4 indicates a memory cell MC (which will hereinafter be called “selected memory cell MCr”) to be subjected to data reading.

At the time of data reading, a control voltage of, for example, about 3V is applied to the control gate line CG0 (CG) to which the other electrode of the capacitor portion C of the selected memory cell MCr is connected. To the other control gate line CG1 (CG) is applied a voltage of, for example, 0V. To the data program•erase bit lines WBL0 and WBL0 (WBL) to which one of the electrodes of the data program•erase capacitor portion CWE of the selected memory cell MCr is connected is applied a voltage of, for example, about 0V. To the select line GS to which the gate electrode of the select MIS•FET QS of the selected memory cell MCr is connected is applied a voltage of, for example, about 3V. To the data read bit line RBL is applied a voltage of, for example, about 1V. To the source line SL is applied, for example, about 0V. By these operations, under the conditions that the data read MIS•FET QR of the selected memory cell MCr to be subjected to data reading is turned ON, whether the data stored in the selected memory cell MCr is either 0 or 1 is read, depending on whether the drain current flows into the channel of the data read MIS•FET QR or not.

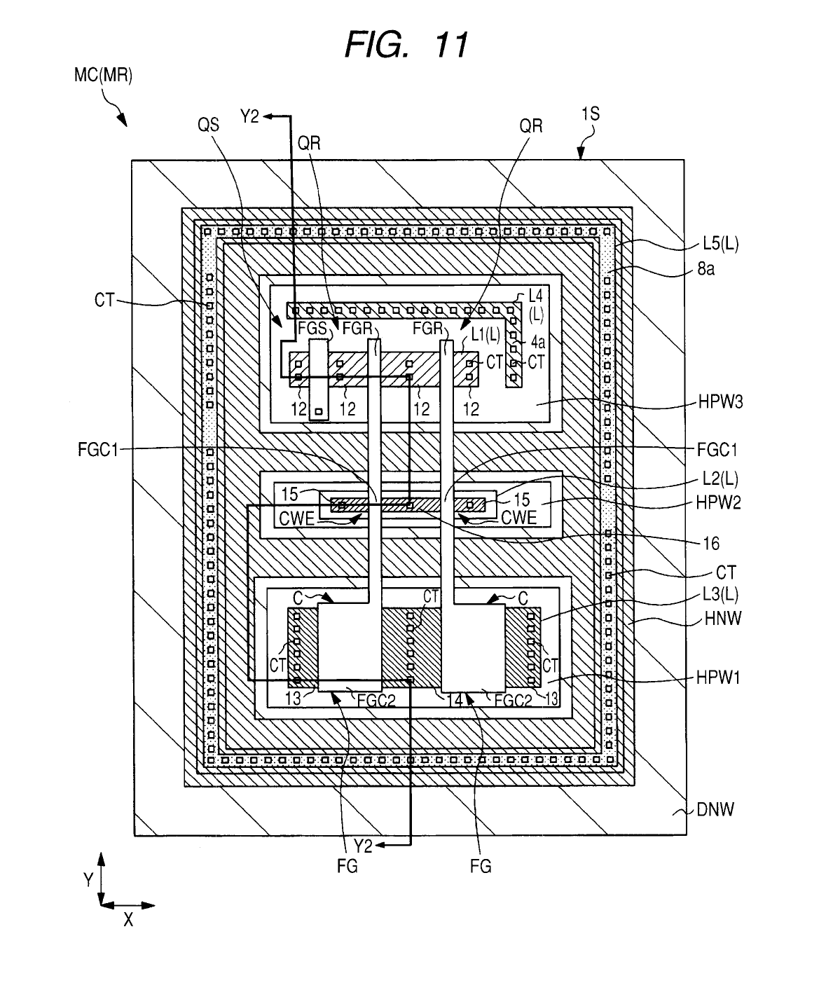

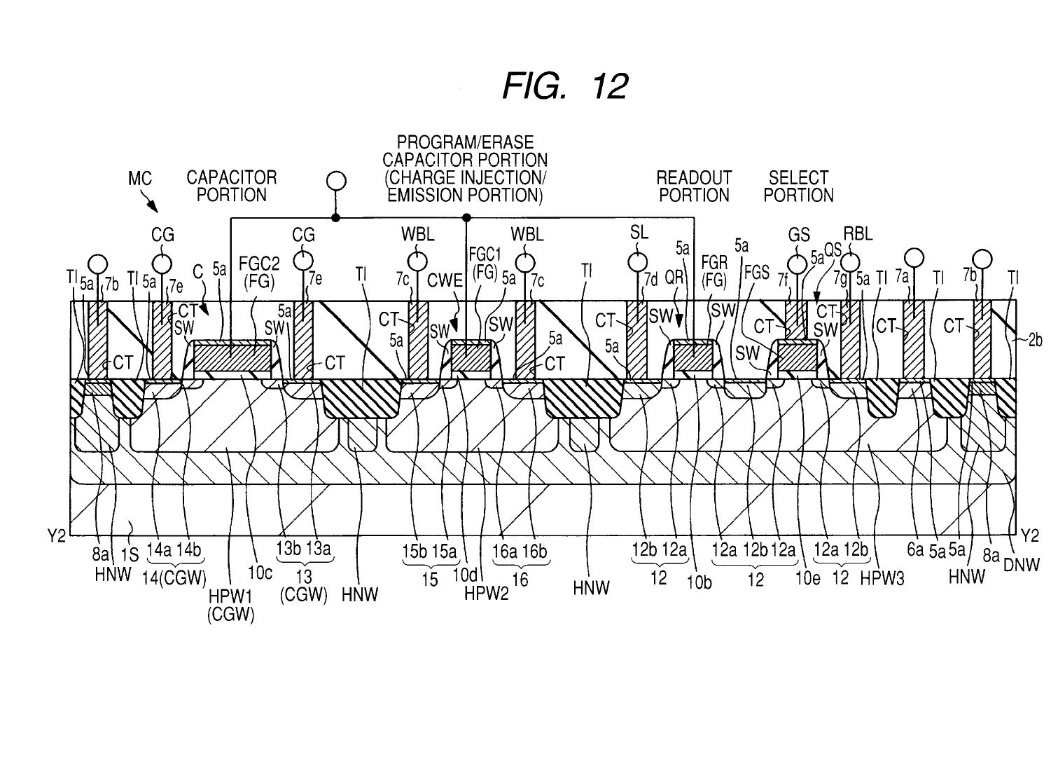

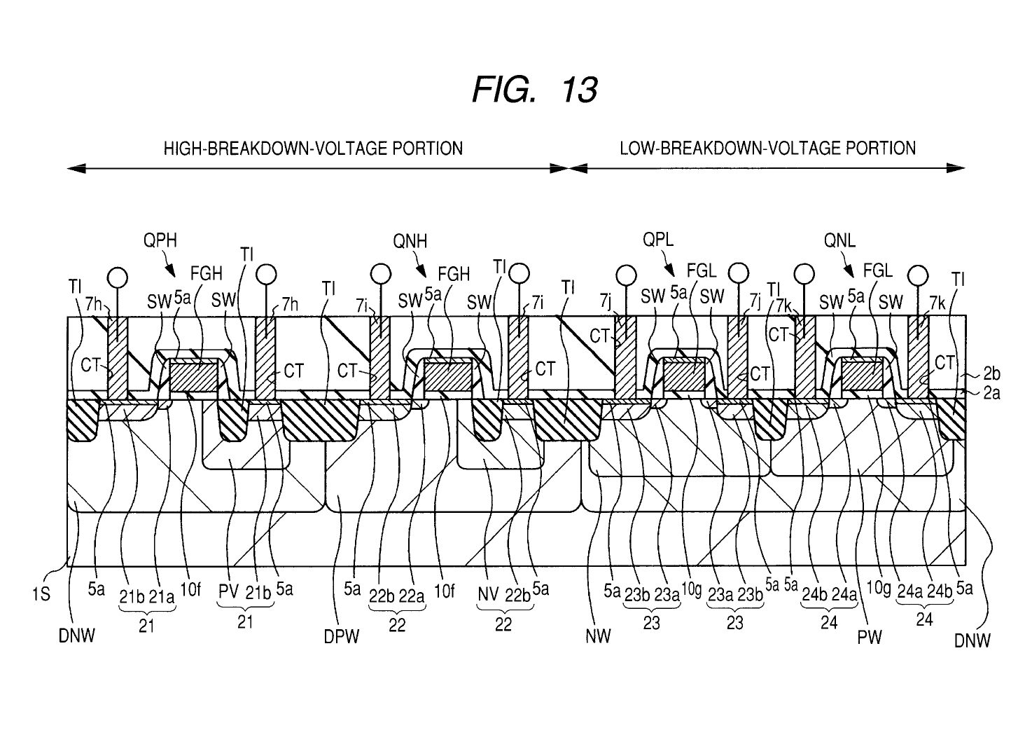

FIG. 11 is a plan view of a memory cell MC of the flash memory corresponding to one bit in the semiconductor device of Embodiment 1; FIG. 12 is a cross-sectional view taken along a line Y2-Y2 of FIG. 11; and FIG. 13 is a fragmentary cross-sectional view of the main circuit region of the semiconductor device of Embodiment 1. FIG. 11 is partially hatched to facilitate understanding of it.

The semiconductor device of Embodiment 1 is, for example, an LCD driver circuit (main circuit). A semiconductor chip equipped therein with this LCD driver circuit has a flash memory for storing desired data of a relatively small capacity relating to the LCD driver circuit and the like.

The constitution example of the flash memory will be described based on FIGS. 11 and 12.

The p-type substrate 1S has, at the main surface (first main surface) thereof, the above-described trench type isolation portions TI for defining active regions L (L1, L2, L3, L4 and L5). In a buried n-well (first well) DNW (“n” means a first conductivity type) formed in this substrate 1S, p wells (“p” means second conductivity type) HPW1, HPW2 and HPW3 and n wells HNW are formed. The p wells HPW1, HPW2 and HPW3 are enclosed in the buried well DNW while electrically isolated from each other by the buried well DNW and n wells HNW.

These p wells HPW1 to HPW3 contain a p type impurity such as boron (B). The p well HPW3 has, on a portion of the upper layer thereof, a p⁺ type semiconductor region 6a. The p⁺ semiconductor region 6a contains an impurity similar to that contained in the p well HPW3, but the impurity concentration in the p⁺ type semiconductor region 6a is adjusted to be higher than that that of the p well HPW3. This p⁺ type semiconductor region 6a is electrically connected to a conductor portion 7a in a contact hole CT formed in an interlayer insulating film (insulating film) 2b over the main surface of the substrate 1S. A silicide layer 5a, for example, cobalt silicide is formed over a portion of the surface layer of the p⁺ type semiconductor region 6a to which this conductor portion 7a is contiguous.

The n well HNW contains an n type impurity such as phosphorus (P) or arsenic (As). This n well HNW has, over a portion of the upper layer thereof, an n⁺ type semiconductor region 8a. The n⁺ type semiconductor region 8a contains an impurity similar to that contained in the n well HNW, but the impurity concentration in the n⁺ type semiconductor region 8a is adjusted to be higher than that that of the n well HNW. This n⁺ type semiconductor region 8a is separated from the p wells HPW1 to HPW3 so that it is not brought into contact with the p wells HPW1 to HPW3. In other words, a portion of the buried n-well DNW exists between the n⁺ type semiconductor region 8a and the p wells HPW1 to HPW3. The n⁺ type semiconductor region 8a is electrically connected to a conductor portion 7b in a contact hole CT formed in the interlayer insulating film 2b. A silicide layer 5a is formed over a portion of the surface layer of the n⁺ type semiconductor region 8a to which this conductor portion 7b is contiguous.

The memory cell MC formed in the memory cell array MR of the flash memory of Embodiment 1 is equipped with a floating gate electrode FG, a data program•erase capacitor portion CWE, a data readout MIS•FET QR and a capacitor portion C.

The floating gate electrode FG is a portion for storing charges which contribute to the storage of data. This floating gate electrode FG is made of a conductor film such as low resistance polycrystalline silicon and is in the electrically floating form (isolated from another conductor). A silicide layer 5a is formed on the upper surface of the floating gate electrode FG.

This floating gate electrode FG, as illustrated in FIG. 11, extends along the first direction Y so as to two-dimensionally overlap with the p wells HPW1, HPW2 and HPW3 which are adjacent to each other.

At the first position where this floating gate electrode FG two-dimensionally overlaps with the active region L2 of the p well (second well) HPW2, the data program•erase capacitor portion CWE is placed. The data program•erase capacitor portion CWE has a capacitor electrode (first electrode) FGC1, a capacitor insulating film (first insulating film) 10d, p type semiconductor region 15, n type semiconductor region 16, and a p well HPW2.

The capacitor electrode FGC1 is formed as a part of the floating gate electrode FG and is a portion for forming the other electrode of the capacitor portion CWE. The capacitor insulating film 10d is made of, for example, silicon oxide and is formed between the capacitor electrode FGC1 and substrate 1S (p well HPW2). The capacitor insulating film 10d has a thickness adjusted to, for example, 10 nm or greater but not greater than 20 nm. In the capacitor portion CWE according to Embodiment 1, electrons are injected from the p well HPW2 to the capacitor electrode FGC1 via the capacitor insulating film 10d or emitted from the capacitor electrode FGC1 to the p well HPW2 via the capacitor insulating film 10d during data rewriting so that the thickness of the capacitor insulating film 10d is adjusted to be small, more specifically, about 13.5 nm. The thickness of the capacitor insulating film 10d is adjusted to 10 nm or greater because when it is thinner than that, the reliability of the capacitor insulating film 10d cannot be ensured. The thickness of the capacitor insulating film 10d is adjusted to 20 nm or less because a film exceeding this thickness cannot allow easy passage of electrons therethrough and prevents smooth data rewriting.

The p type semiconductor region 15 and n type semiconductor region 16 of the capacitor portion CWE are formed in self alignment with the capacitor electrode FGC1 at positions where the semiconductor regions sandwich the capacitor electrode FGC1 therebetween in the p well HPW2. The semiconductor region 15 has a p⁻ type semiconductor region 15a on a channel side and a p⁺ type semiconductor region 15b connected to the region 15a. The p⁻ type semiconductor region 15a and p⁺ type semiconductor region 15b contain impurities of the same conductivity type such as boron (B), but the impurity concentration of the p⁺ type semiconductor region 15b is adjusted to be higher than the impurity concentration of the p⁻ type semiconductor region 15a. The semiconductor region 16 has an n⁻ type semiconductor region 16a on the channel side and an n⁺ type semiconductor region 16b connected to the region 16a. The n⁻ type semiconductor region 16a and n⁺ type semiconductor region 16b contain impurities of the same conductivity type such as arsenic (As) or phosphorus (P), but the impurity concentration of the n⁺ type semiconductor region 16b is adjusted to be higher than the impurity concentration of the n⁻ type semiconductor region 16a. The p type semiconductor region 15, n type semiconductor region 16 and p well HPW2 are portions constituting the one electrode of the capacitor portion CWE. The p type semiconductor region 15 and n type semiconductor region 16 are electrically connected to a conductor portion 7c in a contact hole CT formed in the interlayer insulating film 2b. This conductor portion 7c is electrically connected to the data program•erase bit line WBL. A silicide layer 5a is formed over a portion of the surface layer of the p⁺ type semiconductor region 15b and n⁺ type semiconductor region 16b to which the conductor portion 7c is contiguous.

The following is a reason why the flash memory of this Embodiment has the n type semiconductor region 16. Addition of the n type semiconductor region 16 accelerates the formation of an inversion layer below the capacitor electrode FGC1 at the time of programming data. Electrons are minority carriers in a p type semiconductor, while they are majority carriers in an n type semiconductor. Formation of the n⁺ type semiconductor region 16 facilitates supply of injected electrons to the inversion layer just below the capacitor electrode FGC1. As a result, an effective coupling capacity can be increased and the potential of the capacitor electrode FGC1 can be controlled efficiently. Accordingly, the data programming can be carried out at a higher and more stable speed.

At the second position where the floating gate electrode FG two-dimensionally overlaps with the active region L1 of the p well (third well) HPW3, the data readout MIS•FET QR is placed. The data readout MIS•FET QR is equipped with a gate electrode (second electrode) FGR, a gate insulating film (second insulating film) 10b and a pair of n type semiconductor regions 12 and 12. The channel of the data readout MIS•FET QR is formed in the upper portion of the p well HPW3 where the gate electrode FGR and active region L1 two-dimensionally overlap with each other.

The gate electrode FGR is formed as a portion of the floating gate electrode FG. The gate insulating film 10b is made of, for example, silicon oxide and is formed between the gate electrode FGR and substrate 1S (p well HPW3). The gate insulating film 10b has a thickness of, for example, about 13.5 nm. A pair of n type semiconductor regions 12 and 12 of the data readout MIS•FET QR are formed in self alignment with the gate electrode FGR at positions where the semiconductor regions sandwich therebetween the gate electrode FGR in the p well HPW3. The pair of n type semiconductor regions 12 and 12 of the data readout MIS•FET QR each has an n⁻ type semiconductor region 12a on the channel side and an n⁺ type semiconductor region 12b connected to the region 12a. The n⁻ type semiconductor region 12a and n⁺ type semiconductor region 12b contain impurities of the same conductivity type such as phosphorus (P) or arsenic (As). The impurity concentration of the n⁺ type semiconductor region 12b is adjusted to be higher than that of the n⁻ type semiconductor region 12a. One of the semiconductor regions 12 and 12 of the data readout MIS•FET QR is electrically connected to a conductor portion 7d in a contact hole CT formed in the interlayer insulating layer 2b. The conductor portion 7d is electrically connected to the source line SL. A silicide layer 5a is formed over a portion of the surface layer of the n⁺ type semiconductor region 12b to which this conductor portion 7d is contiguous. The other one of the semiconductor regions 12 and 12 of the data readout MIS•FET QR is shared by one of the n type semiconductor regions 12 for source and drain of the select MIS•FET QS.

The select MIS•FET QS is equipped with a gate electrode FGS, a gate insulating film 10e and a pair of n type semiconductor regions 12 and 12 for source and drain. The channel of the select MIS•FET QS is formed in the upper portion of the p well HPW3 where the gate electrode FGS and active region L1 two-dimensionally overlap with each other.

The gate electrode FGS is made of, for example, low-resistance polycrystalline silicon and it has, on the upper surface thereof, a silicide layer 5a. This gate electrode FGS is electrically connected to a conductor portion 7f in a contact hole CT formed in the interlayer insulating film 2b. The conductor portion 7f is electrically connected to the select line GS. The gate insulating film 10e is made of, for example, silicon oxide and is formed between the gate electrode FGS and substrate 1S (p well HPW3). This gate insulating film 10e has a thickness of, for example, about 13.5 nm. The constitution of the pair of n type semiconductor regions 12 and 12 of the select MIS•FET QS is similar to that of the n type semiconductor region 12 of the data readout MIS•FET QR. The other one of the n type semiconductor regions 12 of the select MIS•FET QS is electrically connected to a conductor portion 7g in a contact hole CT formed in the interlayer insulating film 2b. To the conductor portion 7g is electrically connected the data readout bit line RBL. A silicide layer 5a is formed over a portion of the surface layer of the n⁺ type semiconductor region 12b with which the conductor portion 7g is in contact.

At the position where the floating gate electrode FG two-dimensionally overlaps with the p well (fourth well) HPW1, the capacitor portion C is formed. The capacitor portion C is equipped with a control gate electrode CGW, capacitor electrode (third electrode) FGC2, capacitor insulating film (third insulating film) 10c, p type semiconductor region 13, n type semiconductor region 14 and p well HPW1.

The capacitor electrode FGC2 is formed as a portion of the floating gate electrode FG opposite to the control gate electrodes CGW and it constitutes one of the electrodes of the capacitor portion C. The gate of the memory cell MC having such a single-layer structure facilitates the alignment, upon manufacture of the flash memory, of the memory cell MC and an element of the main circuit, whereby the manufacturing time and cost of a semiconductor device can be reduced.

The length of the capacitor electrode FGC2 in the second direction X is adjusted to be longer than the length of the capacitor electrode FGC1 of the data program•erase capacitor portion CWE or the length of the gate electrode FGR of the data readout MIS•FET QR in the second direction X. This makes it possible to secure a large plane area of the capacitor electrode FGC2, thereby increasing a coupling ratio and improving a voltage supply efficiency from the control gate line CGW.

The capacitor insulating film 10c is made of, for example, silicon oxide and is formed between the capacitor electrode FGC2 and substrate 1S (p well HPW1). The capacitor insulating film 10c is formed simultaneously with the gate insulating films 10b and 10e and capacitor insulating film 10d by the thermal oxidation step employed therefor. Its thickness is, for example, about 13.5 nm.

The p type semiconductor region 13 and n type semiconductor region 14 of the capacitor portion C are formed in self alignment with the capacitor electrode FGC2 at positions where the semiconductor regions sandwich the capacitor electrode FGC2 therebetween in the p well HPW1. The semiconductor region 13 is equipped with a p⁻ type semiconductor region 13b on a channel side and a p⁺ type semiconductor region 13a connected to the region 13b. The p⁻ type semiconductor region 13b and the p⁺ type semiconductor region 13a contain impurities of the same conductivity type such as boron (B), but the impurity concentration of the p⁺ type semiconductor region 13a is adjusted to be higher than that of the p⁻ type semiconductor region 13b. The semiconductor region 14 is equipped with an n⁻ type semiconductor region 14b on the channel side and an n⁺ type semiconductor region 14a connected to the region 14b. The n⁻ type semiconductor region 14b and the n⁺ type semiconductor region 14a contain impurities of the same conductivity type such as arsenic (As) or phosphorus (P), but the impurity concentration of the n⁺ type semiconductor region 14a is adjusted to be higher than that of the n⁻ type semiconductor region 14b. The p type semiconductor region 13, n type semiconductor region 14, and p well HPW1 are portions constituting the control gate electrode CGW (the other electrode) of the capacitor portion C. These p type semiconductor region 13 and n type semiconductor region 14 are electrically connected to a conductor portion 7e in a contact hole CT formed in the interlayer insulating film 2b. The conductor portion 7e is electrically connected to the control gate line CG. A silicide layer 5a is formed over a portion of the surface layer of the p⁺ type semiconductor region 13a and n⁺ type semiconductor region 14a to which this conductor portion 7e is contiguous.

The following is a reason why the flash memory of this Embodiment has the n type semiconductor region 14. Addition of the n type semiconductor region 14 enables smooth supply of electrons to a portion just below the capacitor insulating film 10c at the data erasing operation. This makes it possible to form an inversion layer below the capacitor electrode FGC2 promptly, thereby fixing the p well HPW1 to −9V promptly. As a result, an effective coupling capacity can be increased and the potential of the capacitor electrode FGC2 can be controlled efficiently. Accordingly, data can be erased at a higher and more stable speed.

Since the flash memory according to Embodiment 1 has both the p type semiconductor regions 15 and 13 and the n type semiconductor regions 16 and 14 in the capacitor portion (charge injection/emission portion) CWE and capacitor portion C, the n type semiconductor region 16 acts as a supply source of electrons in the capacitor portion (charge injection/emission portion) CWE, while the n type semiconductor region 14 acts as a supply source of electrons to the inversion layer in the capacitor portion C. This results in the improvement of the data programming speed and data erasing speed of the memory cell MC.

A constitution example of elements of the LCD driver circuit will next be described based on FIG. 13.

A high-breakdown-voltage portion and a low-breakdown-voltage portion are MIS•FET formation regions constituting the LCD driver circuit.

In the active region of the high-breakdown-voltage portion encompassed by the isolation portion TI, high-breakdown-voltage p channel MIS•FET QPH and n channel MIS•FET QNH are placed. The operating voltage of MIS•FET QPH and QNH of the high-breakdown-voltage portion is, for example, about 25V.

The high-breakdown-voltage p channel type MIS•FET QPH is equipped with a gate electrode FGH, a gate insulating film 10f and a pair of p type semiconductor regions 21 and 21. The channel of this MIS•FET QPH is formed in the upper portion of a buried n well DNW where the gate electrode FGH and active region two-dimensionally overlap.

The gate electrode FGH is made of, for example, low-resistance polycrystalline silicon and it has, on the upper surface thereof, a silicide layer 5a. The gate insulating film 10f is made of, for example, silicon oxide and it is formed between the gate electrode FGH and substrate 1S (buried n well DNW).

The pair of p type semiconductor regions 21 and 21 of the high-breakdown-voltage p channel MIS•FET QPH are formed in the buried n well DNW so as to sandwich the gate electrode FGH between them.

One of the pair of p type semiconductor regions 21 and 21 has a p⁻ type semiconductor region 21a on the channel side and a p⁺ type semiconductor region 21b connected to the region 21a. The p⁻ type semiconductor region 21a and p⁺ type semiconductor region 21b contain impurities of the same conductivity type, for example, boron (B), but the impurity concentration of the p⁺ type semiconductor region 21b is set higher than that of the p⁻ type semiconductor region 21a.

The other one of the pair of p type semiconductor regions 21 and 21 has a p type semiconductor region PV on the channel side and a p⁺ type semiconductor region 21b connected to the region PV. The impurity concentration of the p type semiconductor region PV is set higher than that of a buried p well DPW and lower than that of the p⁺ type semiconductor region 21b.

The semiconductor regions 21 and 21 of the high-breakdown-voltage MIS•FET QPH are electrically connected to a conductor portion 7h in a contact hole CT formed in the interlayer insulating film 2b and insulating film 2a. A silicide layer 5a is formed over a portion of the surface layer of the p⁺ type semiconductor region 21b with which the conductor portion 7h is in contact.

The high-breakdown-voltage n channel type MIS•FET QNH is equipped with a gate electrode FGH, a gate insulating film 10f and a pair of n type semiconductor regions 22 and 22. The channel of this MIS•FET QNH is formed in the upper portion of the buried p well where the gate electrode FGH and active region two-dimensionally overlap.

The gate electrode FGH of the high-breakdown-voltage MIS•FET QNH is made of, for example, low-resistance polycrystalline silicon and it has, on the upper surface thereof, a silicide layer 5a. The gate insulating film 10f of the high-breakdown-voltage MIS•FET QNH is made of, for example, silicon oxide and it is formed between the gate electrode FGH and substrate 1S (buried p well DPW).

The pair of n type semiconductor regions 22 and 22 of the high-breakdown-voltage MIS•FET QNH are formed in the buried p well DPW so as to sandwich the FGH between them.

One of the pair of n type semiconductor regions 22 and 22 has an n⁻ type semiconductor region 22a on the channel side and an n⁺ type semiconductor region 22b connected to the region 22a. The n⁻ type semiconductor region 22a and n⁺ type semiconductor region 22b contain impurities of the same conductivity type, for example, phosphorus or arsenic (As), but the impurity concentration of the n⁺ type semiconductor region 22b is set higher than that of the n⁻ type semiconductor region 22a.

The other one of the pair of p type semiconductor regions 22 and 22 has an n type semiconductor region NV on the channel side and an n⁺ type semiconductor region 22b connected to the region NV. The impurity concentration of the n type semiconductor region NV is set higher than that of the buried n well DNW and lower than that of the n⁺ type semiconductor region 22b.

The semiconductor regions 22 and 22 of the high-breakdown-voltage MIS•FET NPH are electrically connected to a conductor portion 7i in a contact hole CT formed in the interlayer insulating film 2b and insulating film 2a. A silicide layer 5a is formed over a portion of the surface layer of the n⁺ type semiconductor region 22b with which the conductor portion 7i is in contact.

In an active region of the low-breakdown-voltage portion encompassed by the isolation portion TI, a p channel type MIS•FET QPL and an n channel type MIS•FET QNL are placed. The operating voltage of MIS•FET QPL and MIS•FET QNL of the low-breakdown-voltage portion is, for example, about 6.0V. The MIS•FET QPL and MIS•FET QNL of the low-breakdown-voltage portion have a gate insulating film thinner and have a gate electrode length, in the gate length direction, smaller than those of the MIS•FET QNH and MIS•FET QPH of the high-breakdown-voltage portion.

Some of the MIS•FET QPL and MIS•FET QNL of the low-breakdown-voltage portion have an operating voltage of 1.5V in addition to those having an operating voltage of 6.0V. The MIS•FET having an operating voltage of 1.5V is disposed because of operation at higher speed than that of the MIS•FET having an operating voltage of 6.0V. It constitutes, together with another MIS•FET, the LCD driver circuit. The gate insulating film of the MIS•FET having an operating voltage of 1.5V is thinner than that of the MIS•FET having an operating voltage of 6.0V and it has a thickness of from about 1 to 3 nm. In order to simplify the description, only the MIS•FET of the high-breakdown-voltage portion having an operating voltage of 25V and the MIS•FET of the low-breakdown-voltage portion having an operating voltage of 6.0V are illustrated mainly in the drawings and the MIS•FET having an operating voltage of 1.5V is not illustrated therein.

The low-breakdown-voltage p channel type MIS•FET QPL is equipped with a gate electrode FGL, a gate insulating film 10g and a pair of p type semiconductor regions 23 and 23. The channel of this MIS•FET QPL is formed in the upper portion of the buried n well NW where the gate electrode FGL and active region two-dimensionally overlap.

The gate electrode FGL is made of, for example, low-resistance polycrystalline silicon and it has, on the upper surface thereof, a silicide layer 5a. The gate insulating film 10g is made of, for example, silicon oxide and it is formed between the gate electrode FGL and substrate 1S (n well NW).

The pair of p type semiconductor regions 23 and 23 of the low-breakdown-voltage p channel MIS•FET QPL are formed in the n well NW so as to sandwich the gate electrode FGL between them.

The pair of p type semiconductor regions 23 and 23 each has a p⁻ type semiconductor region 23a on the channel side and a p⁺ type semiconductor region 23b connected to the region 23a. The p⁻ type semiconductor region 23a and p⁺ type semiconductor region 23b contain impurities of the same conductivity type, for example, boron (B), but the impurity concentration of the p⁺ type semiconductor region 23b is set higher than that of the p⁻ type semiconductor region 23a.

The semiconductor regions 23 and 23 of the low-breakdown-voltage MIS•FET QPL are electrically connected to a conductor portion 7j of a contact hole CT formed in the interlayer insulating film 2b and insulating film 2a. A silicide layer 5a is formed over a portion of the surface layer of the p⁺ type semiconductor region 23b with which the conductor portion 7j is in contact.

The low-breakdown-voltage n channel type MIS•FET QNL is equipped with a gate electrode FGL, a gate insulating film 10g and a pair of n type semiconductor regions 24 and 24. The channel of this MIS•FET QNL is formed in the upper portion of the buried p well PW where the gate electrode FGL and active region two-dimensionally overlap.

The gate electrode FGL of the low-breakdown-voltage MIS•FET QNL is made of, for example, low-resistance polycrystalline silicon and it has, on the upper surface thereof, a silicide layer 5a. The gate insulating film 10g of the low-breakdown-voltage MIS•FET QNL is made of, for example, silicon oxide and is formed between the gate electrode FGL and substrate 1S (p well PW).

The pair of n type semiconductor regions 24 and 24 of the low-breakdown-voltage MIS•FET QNL are formed in the p well PW so as to sandwich the gate electrode FGL between them.

The pair of n type semiconductor regions 24 and 24 each has an n⁻ type semiconductor region 24a on the channel side and an n⁺ type semiconductor region 24b connected to the region 24a. The n⁻ type semiconductor region 24a and n⁺ type semiconductor region 24b contain impurities of the same conductivity type, for example, phosphorus or arsenic (As), but the impurity concentration of the n⁺ type semiconductor region 24b is set higher than that of the n⁻ type semiconductor region 24a.

The semiconductor regions 24 and 24 of the low-breakdown-voltage MIS•FET QNL are electrically connected to a conductor portion 7k in a contact hole CT formed in the interlayer insulating film 2b and insulating film 2a. A silicide layer 5a is formed over a portion of the surface layer of the n⁺ type semiconductor region 24b with which the conductor portion 7k is in contact.

In such Embodiment 1, as illustrated in FIG. 13, the insulating film 2a is formed in circuit regions other than flash memory such as LCD driver circuit region and peripheral circuit region of the flash memory, while as illustrated in FIG. 12, the insulating film 2a is not formed in the memory cell array MR of the flash memory. This makes it possible to suppress or prevent the leakage of electrons e of the floating gate electrode FG in the memory cell array MR without impairing miniaturization of elements in the circuit regions other than the flash memory such as the LCD driver circuit region and peripheral circuit region of the flash memory. As a result, the resulting flash memory has improved data retention characteristics.

In the semiconductor device (semiconductor chip, substrate 1S) according to Embodiment 1, a single supply source is employed as an external supply source. In Embodiment 1, an external single supply voltage (for example, 3.3V) of the semiconductor device can be converted into a voltage (for example, −9V) to be used at the time of data programming of the memory cell MC by a negative-voltage charge pump circuit (internal charge pump circuit) for LCD driver circuit. In addition, an external single supply voltage (for example, 3.3V) can be converted into a voltage (for example, 9V) to be used at the time of data erasing of the memory cell MC by a positive-voltage charge pump circuit (internal charge pump circuit) for LCD driver circuit. This suggests that the semiconductor device of this embodiment does not need additional internal charge pump circuit for flash memory. It is therefore possible to suppress the circuit scale inside of the semiconductor device to a small level, thereby promoting a size reduction of the semiconductor device.

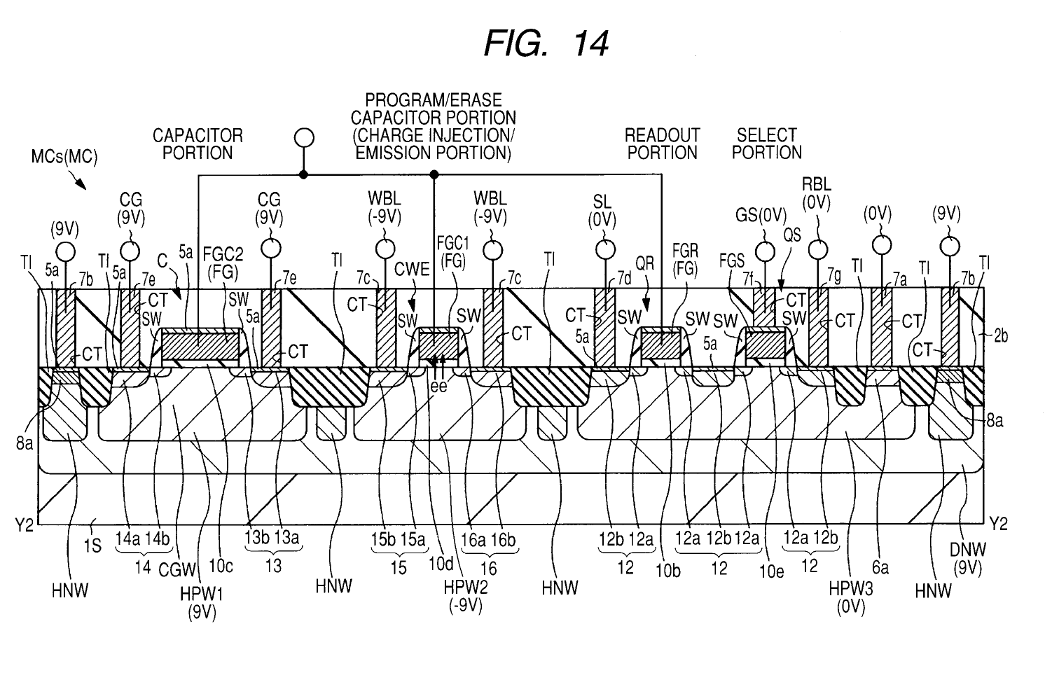

FIG. 14 is a cross-sectional view taken along a line Y2-Y2 of FIG. 11 and illustrates one example of a voltage applied to each portion of the select memory cell MCs at the time of data program operation of the flash memory according to Embodiment 1.

A voltage of, for example, about 9V is applied to the n well HNW and buried n-well DNW via the conductor portion 7b to electrically isolate the substrate 1S from the p wells HPW1 to HPW3. In addition, a positive control voltage of, for example, about 9V is applied to the control gate electrode CGW of the capacitor portion C from the control gate line CG via the conductor portion 7e. A negative voltage of, for example, about −9V is applied to one (p type semiconductor regions 5 and p well HPW2) of the electrodes of the capacitor portion CWE from the program•erase bit line WBL for data via the conductor portion 7c. Via the conductor portion 7a, a voltage of, for example, 0V is applied to the p well HPW3. A voltage of, for example, 0V is applied to the gate electrode FGS of the select MIS•FET QS from the select line GS via the conductor portion 7f. A voltage of, for example, 0V is applied to one of the n type semiconductor regions 12 of the data readout MIS•FET QR from the source line SL via the conductor portion 7d. A voltage of, for example, 0V is applied to one of the n type semiconductor region 12 from the data readout bit line RBL via the conductor portion 7g. By these operations, electrons e of the p well HPW2 of the data program•erase capacitor portion CWE of the selected memory cell MCs are injected into the capacitor electrode FGC1 (floating gate electrode FG) via the capacitor insulating film 10d by means of an FN tunneling current of an entire channel surface to perform data programming.

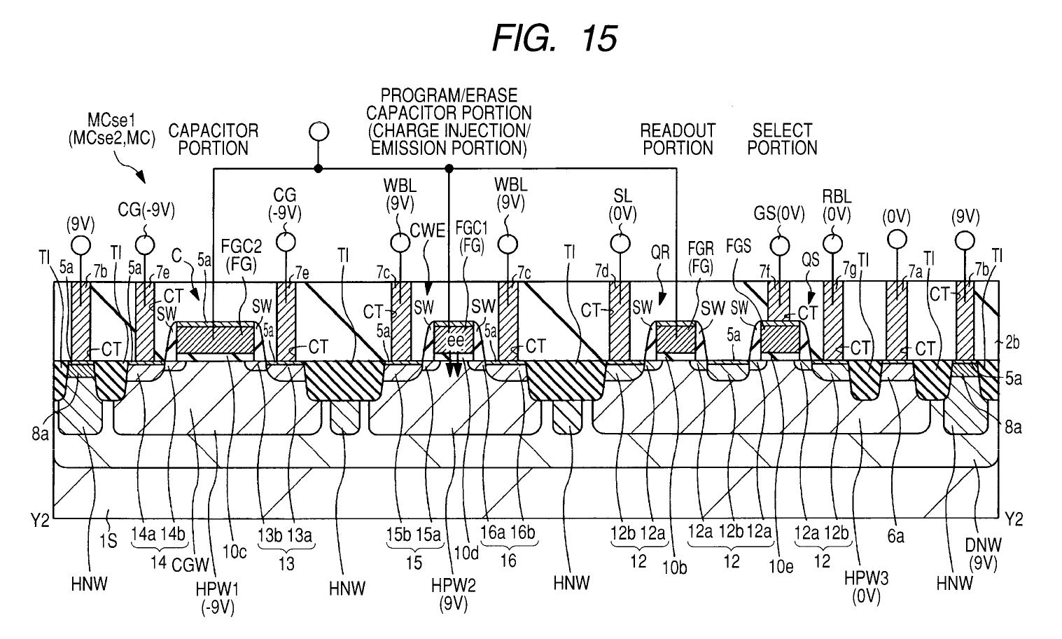

FIG. 15 is a cross-sectional view taken along a line Y2-Y2 of FIG. 11 and illustrates a voltage applied to each portion of the flash memory of Embodiment 1 at the time of data erase operation.

A voltage of, for example, about 9V is applied to the n well HNW and buried n-well DNW via the conductor portion 7b to electrically isolate the substrate 1S from the p wells HPW1 to HPW3. In addition, a negative control voltage of, for example, about −9V is applied to the control gate electrode CGW of the capacitor portion C from the control gate line CG via the conductor portion 7e. A positive voltage of, for example, about 9V is applied to one (p type semiconductor region 5 and p well HPW2) of the electrodes of the capacitor portion CWE from the data program•erase bit line WBL via the conductor portion 7c. Via the conductor portion 7a, a voltage of, for example, 0V is applied to the p well HPW3. A voltage of, for example, 0V is applied to the gate electrode FGS of the select MIS•FET QS from the select line GS via the conductor portion 7f. A voltage of, for example, 0V is applied to one of the n type semiconductor regions 12 of the data readout MIS•FET QR from the source line SL via the conductor portion 7d. A voltage of, for example, 0V is applied to one of the n type semiconductor regions 12 of the select MIS•FET QS from the data readout bit line RBL via the conductor portion 7g. By these operations, electrons e accumulated in the capacitor electrode FGC1 (floating gate electrode FG) of the data program•erase capacitor portion CWE of the selected memory cell MCse1 (MCsec2) are emitted to the p well HPW2 via the capacitor insulating film 10d by means of an FN tunneling current of an entire channel surface to erase data.

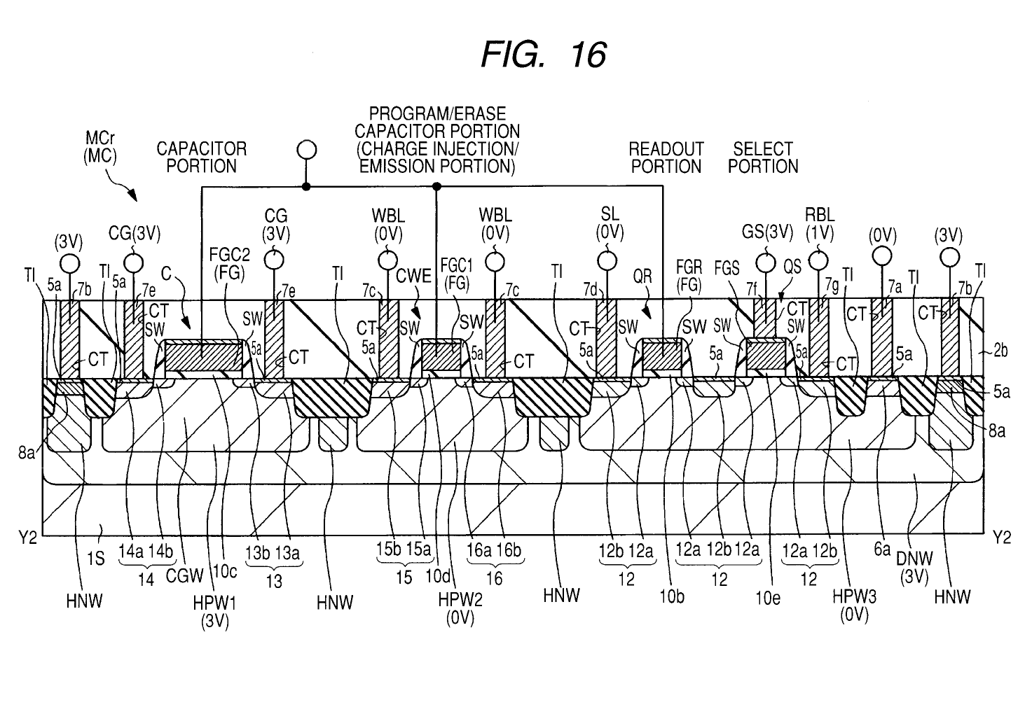

FIG. 16 is a cross-sectional view taken along a line Y2-Y2 of FIG. 11 and illustrates a voltage applied to each portion, at the time of data read operation, of the flash memory according to Embodiment 1.

In data readout, a voltage of, for example, about 3V is applied to the n well HNW and buried n-well DNW via the conductor portion 7b to electrically isolate the substrate 1S from the p wells HPW1 to HPW3. A positive control voltage of, for example, about 3V is applied to the control gate electrode CGW of the capacitor portion C from the control gate line CG via the conductor portion 7e, whereby a positive voltage is applied to the gate electrode FGR of the data readout MIS•FET QR. A voltage of, for example, 0V is applied to the p well HPW3 via the conductor portion 7a. A voltage of, for example, about 3V is applied to the gate electrode FGS of the select MIS•FET QS from the select line GS via the conductor portion 7f. A voltage of, for example, 0V is applied to one of the n type semiconductor regions 12 of the data readout MIS•FET QR from the source line SL via the conductor portion 7d. A voltage of, for example, about 1V is applied to one of the n type semiconductor regions 12 of the select MIS•FET QS from the data readout bit line RBL via the conductor portion 7g. A voltage of, for example, 0V is applied to one (p type semiconductor region 15 and p well HPW2) of the electrodes of the capacitor portion CWE from the data program•erase bit line WBL via the conductor portion 7c. By these operations, under the conditions that the data readout MIS•FET QR of the selected memory cell MCr is turned ON, whether the data stored in the selected memory cell MCr is either 0 or 1 is read, depending on whether the drain current flows into the channel of the data readout MIS•FET QR or not.

According to Embodiment 1 as described above, a data rewrite region (capacitor portion CWE), data read-out region (data readout MIS•FET QR) and capacitance coupled region (capacitor portion C) are formed in the p wells HPW1 to HPW3, respectively and they are isolated by the n well HNW and buried n-well DNW.

The data rewrite region (capacitor portion CWE) and data readout region (data readout MIS•FET QR) are formed in the p wells HPW2 and HPW3, respectively so that stable data rewrite can be realized. The flash memory thus obtained has therefore improved operation reliability.

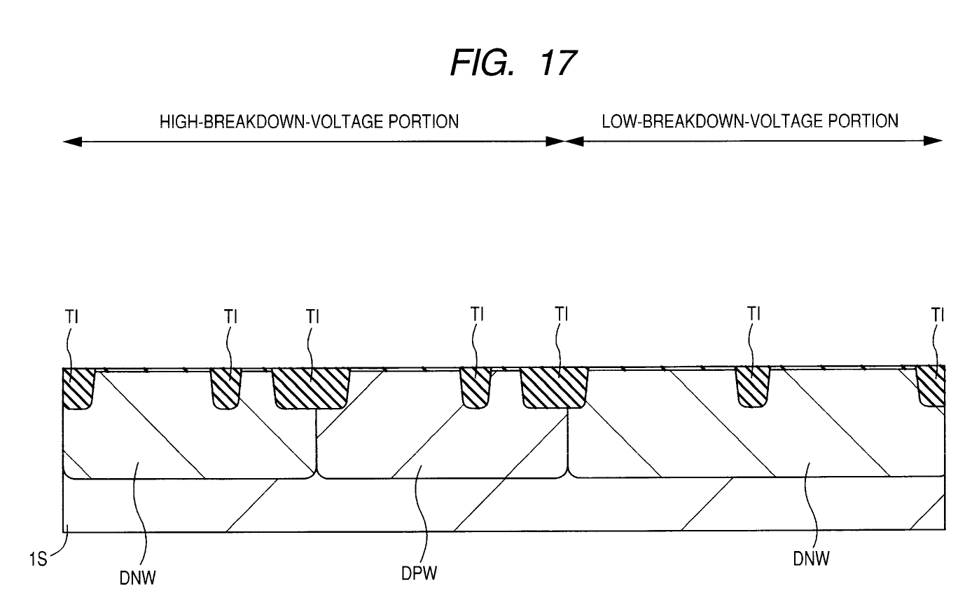

One example of manufacturing methods of the semiconductor device according to Embodiment 1 will next be explained based on FIGS. 17 to 32. FIGS. 17 to 32 are fragmentary cross-sectional views of the same substrate 1S (a thin semiconductor disc called “semiconductor wafer”) during the manufacturing steps of the semiconductor device of Embodiment 1.

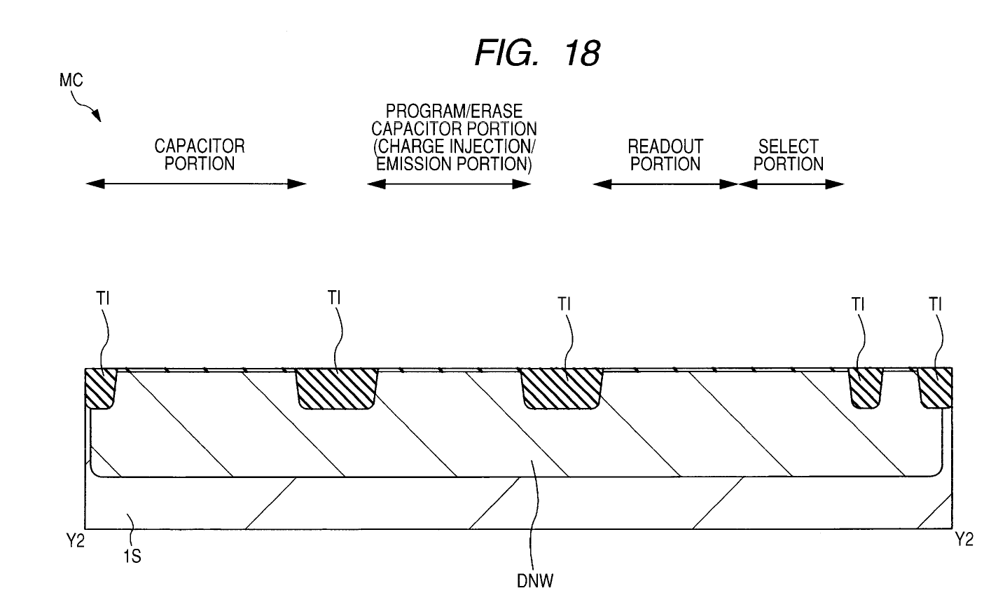

First, as illustrated in FIGS. 17 and 18, a p type substrate 1S (semiconductor wafer) is prepared and a buried p-well DPW is formed in a high-breakdown-voltage portion of the substrate by photolithography (which will hereinafter be called “lithography” simply), ion implantation and the like. The lithography is a step for forming a desired resist pattern and is composed of application of a photoresist (which will hereinafter be called “resist” simply) film, exposure and development. In the ion implantation, with the resist pattern formed over the main surface of the substrate 1S by the lithography as a mask, a desired impurity is selectively introduced into a desired portion of the substrate 1S. The term “resist pattern” as used herein means a pattern from which an impurity introduced region is exposed but with which the other region is covered.

In the high-breakdown-voltage portion, low-breakdown-voltage portion and the memory cell formation region of a flash memory, buried n-wells DNW are formed simultaneously by lithography, ion implantation and the like. After formation of isolation trenches in the isolation region on the main surface of the substrate 1S, an insulating film is filled in the isolation trenches, whereby isolation portions TI in the trench form are formed. Active regions are defined by these isolation portions.

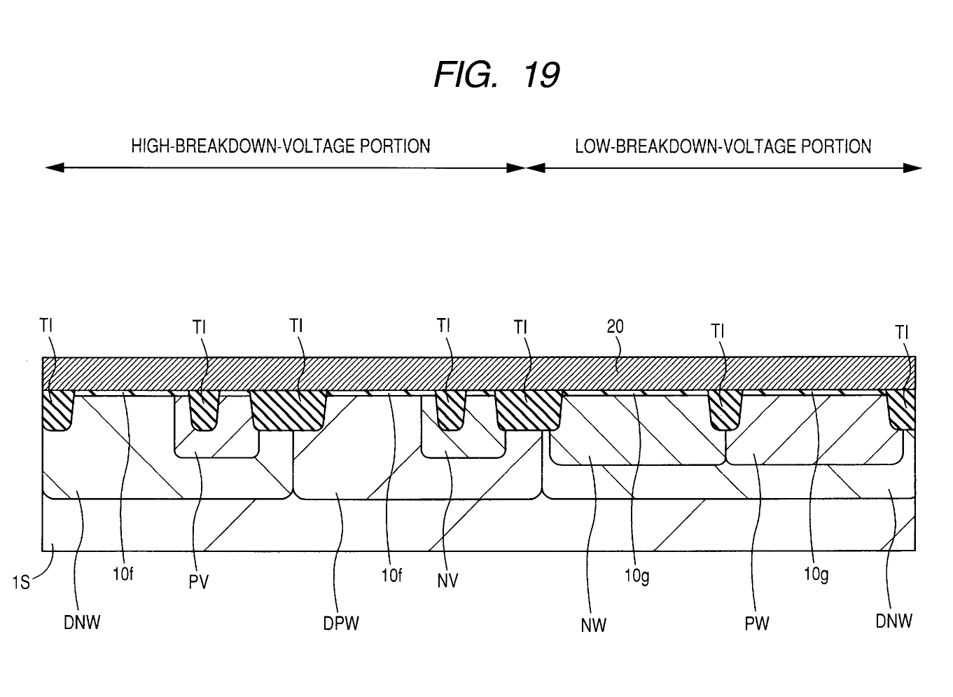

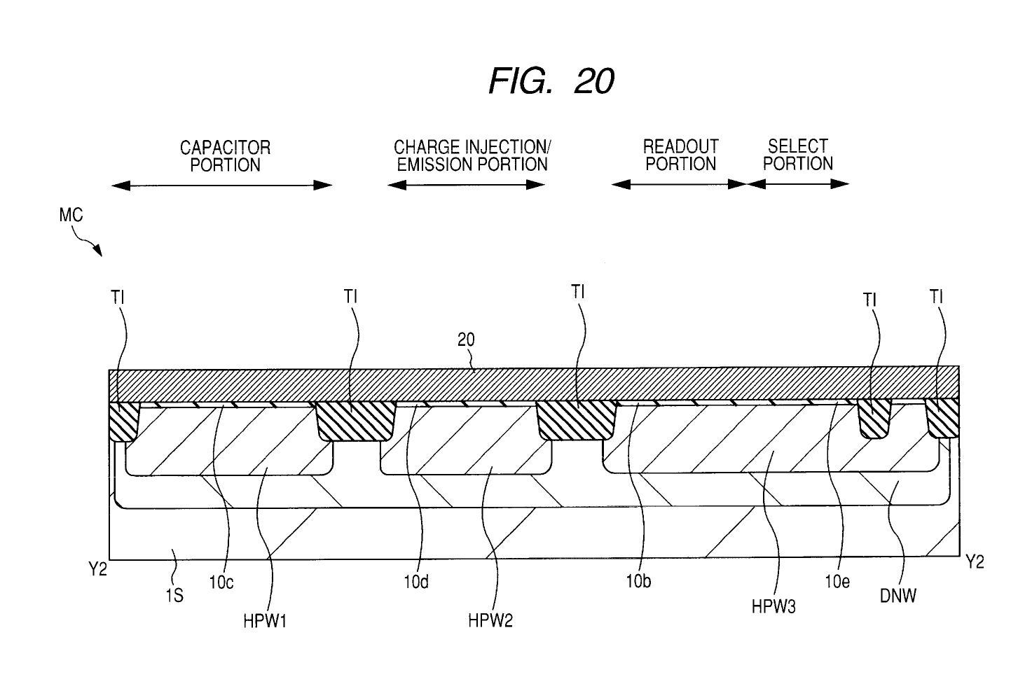

As illustrated in FIGS. 19 and 20, an n type semiconductor region NV is then formed in the formation region of an n channel type MIS•FET in the high-breakdown-voltage portion by lithography, ion implantation and the like. This n type semiconductor region NV has a higher impurity concentration than that of the buried n-well DNW. A p type semiconductor region PV is then formed in the formation region of a p channel type MIS•FET in the high-breakdown-voltage portion by lithography, ion implantation and the like. This p type semiconductor region PV has a higher impurity concentration than that of the buried p-well DPW.

A p well PW is then formed by lithography, ion implantation and the like in the formation region of an n channel type MIS•FET in the low-breakdown-voltage portion. This p well PW is a region having a higher impurity concentration than that of the p type buried well DPW and also a region having a higher impurity concentration than that of the p type semiconductor region PV. An n well NW is then formed in the formation region of a p channel type MIS•FET in the low-breakdown-voltage portion by lithography, ion implantation and the like. This n well NW is a region having a higher impurity concentration than that of the buried n-well DNW and also a region having a higher impurity concentration than that of the n type semiconductor region NV.

In the memory cell array of the flash memory, p wells HPW1 to HPW3 are formed simultaneously by lithography, ion implantation and the like. The p wells HPW1 to HPW3 are regions having a higher impurity concentration than that of the buried p-well DPW and also regions having an impurity concentration of the same level as that of the p type semiconductor region PV.

The above-described relationship in impurity concentration among these buried n-well DNW, buried p-well DPW, n type semiconductor region NV, p type semiconductor region PV, n well NW, p well PW and p wells HPW1 to HPW3 Can be applied to the embodiments which will be described later.

After formation of gate insulating films 10b, 10e, 10f and 10g and capacitor insulating films 10c and 10d by a thermal oxidation process, a conductor film 20 made of, for example, a low resistance polycrystalline silicon film is formed over the main surface (first main surface) of the substrate 1S (semiconductor wafer) by CVD (chemical vapor deposition) or the like process. When the gate insulating film 10f of the MIS•FET in the high-breakdown-voltage portion is formed, its thickness is made greater than that of the gate insulating film 10g of the MIS•FET in the low-breakdown-voltage portion so that it can withstand the breakdown voltage of 25V. The gate insulating film 10f of the MIS•FET in the high-breakdown-voltage portion has a thickness of, for example, 50 to 100 nm. Instead of the above-described oxide film formed by a thermal oxidation process, an insulating film deposited by CVD or the like can be stacked.

In this Embodiment 1, the gate insulating films 10b and 10e and capacitor insulating films 10c and 10d of the nonvolatile memory are formed by the same formation step as that of the gate insulating film 10g of the MIS•FET (MIS•FET having an operating voltage of, for example, 6V) in the low-breakdown-voltage portion. The thicknesses of the gate insulating film 10b and 10e and capacitor insulating films 10c and 10d of the nonvolatile memory are therefore equal to that of the gate insulating film 10g of the MIS•FET in the low-breakdown-voltage portion. For a similar reason to that referred to the insulating film 10a and the like, the gate insulating films 10b, 10e and 10g and capacitor insulating films 10c and 10d each preferably has a thickness of 10 nm or greater but not greater than 20 nm. It has, for example, a thickness of 13.5 nm.

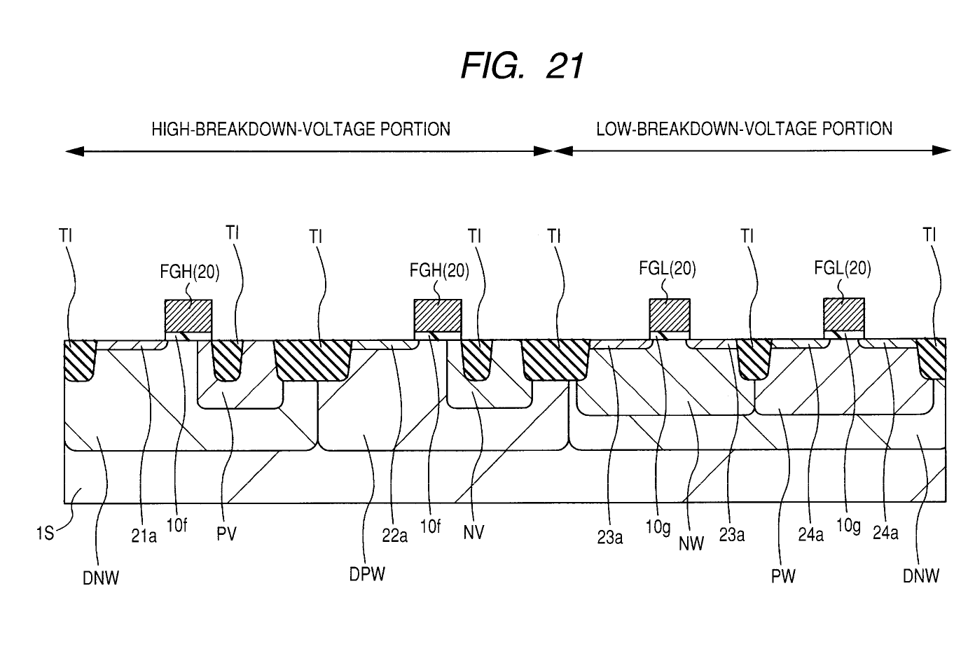

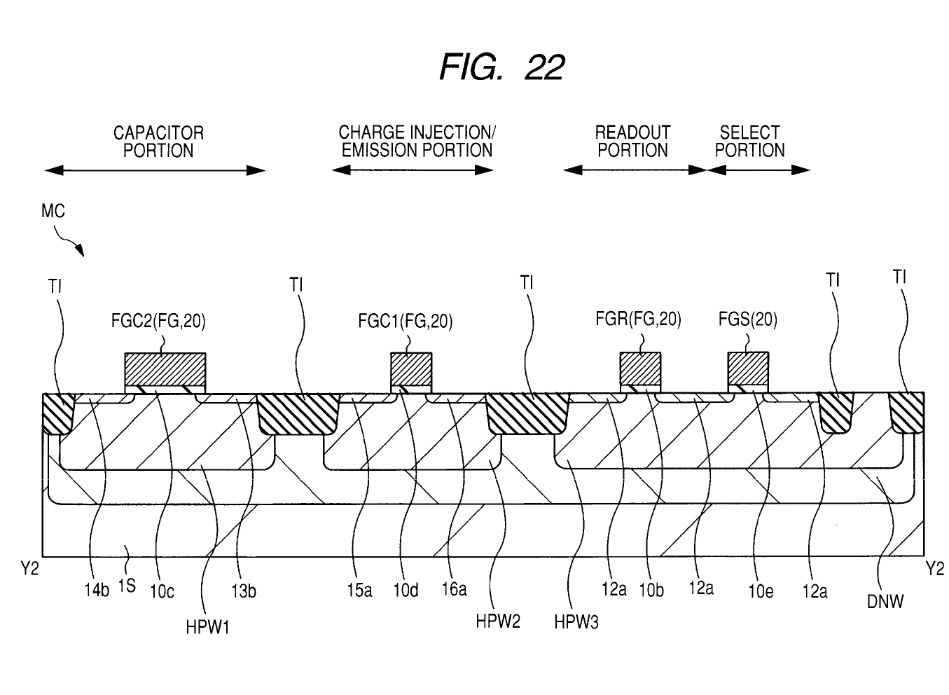

As illustrated in FIGS. 21 and 22, the conductor film 20 is patterned by lithography and etching, whereby gate electrodes FGH, FGL and FGS and floating gates FG (gate electrode FGR and capacitor electrodes FGC1 and FGC2) are formed simultaneously. In the formation region of a p-channel type MIS•FET of the high-breakdown-voltage portion, the formation region of a capacitor portion C and the formation region of a data program•erase capacitor portion CWE, p⁻ type semiconductor regions 21a, 13b and 15a are formed simultaneously by lithography and ion implantation. In the formation region of an channel type MIS•FET of the high-breakdown-voltage portion, the formation region of a data readout MIS•FET QR, the formation region of a capacitor portion C, the formation region of a data write-erase capacitor portion CWE, and the formation region of a select MIS•FET QS, n⁻ type semiconductor regions 22a, 12a, 14b and 16a are then formed simultaneously by lithography, ion implantation and the like. In the formation region of a p channel type MIS•FET of the low-breakdown-voltage portion, a p⁻ type semiconductor region 23a is then formed by lithography, ion implantation and the like. In the formation region of an n-channel type MIS•FET of the low-breakdown-voltage portion, an n⁻ type semiconductor region 24a is formed by lithography, ion implantation and the like.

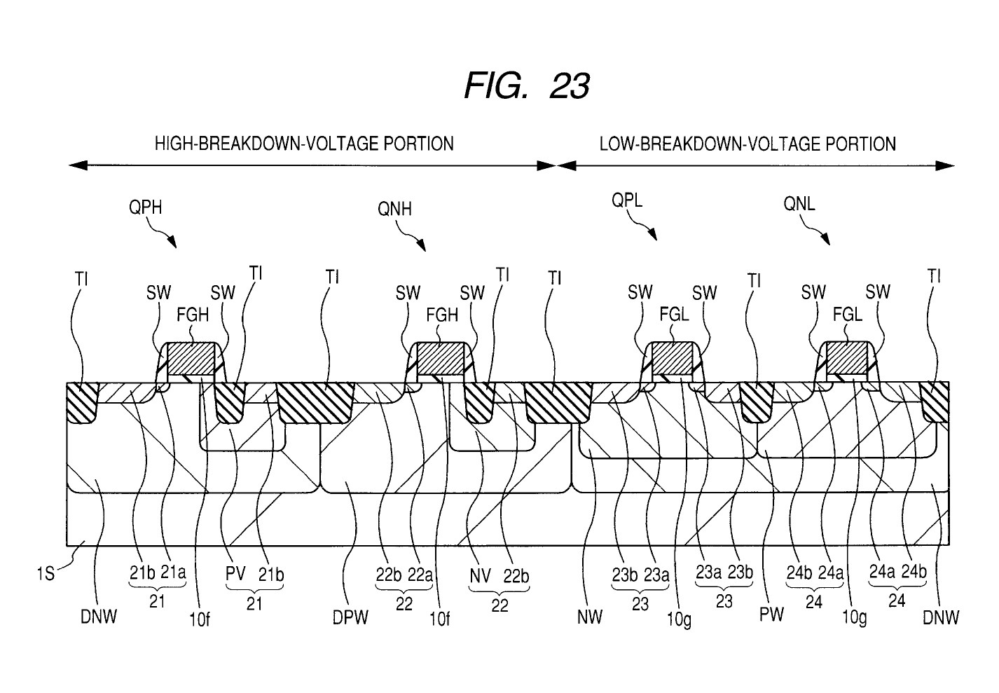

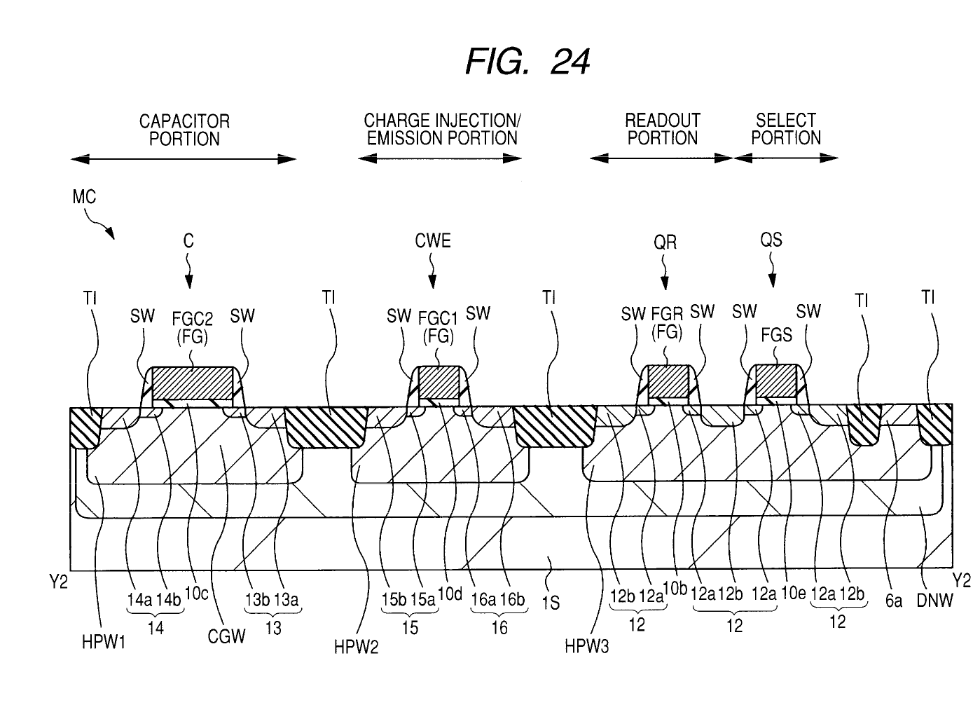

As illustrated in FIGS. 23 and 24, an insulating film made of, for example, silicon oxide is deposited over the main surface of the substrate 1S (semiconductor wafer) by CVD or the like, followed by etch back by anisotropic dry etching, whereby sidewalls SW are formed over the side surfaces of the gate electrodes FGH, FGL, FGR, and FGS and the capacitor electrodes FGC1 and FGC2.

In the formation regions of a p channel type MIS•FET of the high-breakdown-voltage portion and the low-breakdown-voltage portion, the formation regions of a capacitor portion and data program•erase capacitor portion, and an extraction region of the p well HPW3, p⁺ type semiconductor regions 21b, 23b, 13a, 15b and 6a are formed simultaneously by lithography, ion implantation process and the like, whereby in the high-breakdown-voltage portion, p type semiconductor regions 21 for source and drain are formed, followed by the formation of a p channel type MIS•FET QPH; in the low-breakdown-voltage portion, p type semiconductor regions 23 for source and drain are formed, followed by the formation of a p channel type MIS•FET QRL; in the capacitor portion formation region, a p type semiconductor region 13 is formed; and in the formation region of a program•erase capacitor portion, a p type semiconductor region 15 is formed.

In the n-channel type MIS•FET formation region of the high-breakdown-voltage portion, low-breakdown-voltage portion, read-out portion, capacitor portion, program•erase capacitor formation region, and select portion, n⁺ type semiconductor regions 22b, 24b, 12b, 14a and 16b are formed simultaneously by lithography, ion implantation and the like, whereby in the high-breakdown-voltage portion, n type semiconductor regions 22 for source and drain are formed, followed by the formation of an n channel type MIS•FET QNH; in the low-breakdown-voltage portion, n type semiconductor regions 24 for source and drain are formed, followed by the formation of an n channel type MIS•FET QNL; in the read-out portion and select portion, n type semiconductor regions 12 are formed, followed by the formation of a data readout MIS•FET QR and select MIS•FET QS; in the capacitor portion formation region, an n type semiconductor region 14 is formed; and in the program•erase capacitor portion formation region, an n type semiconductor region 16 is formed.

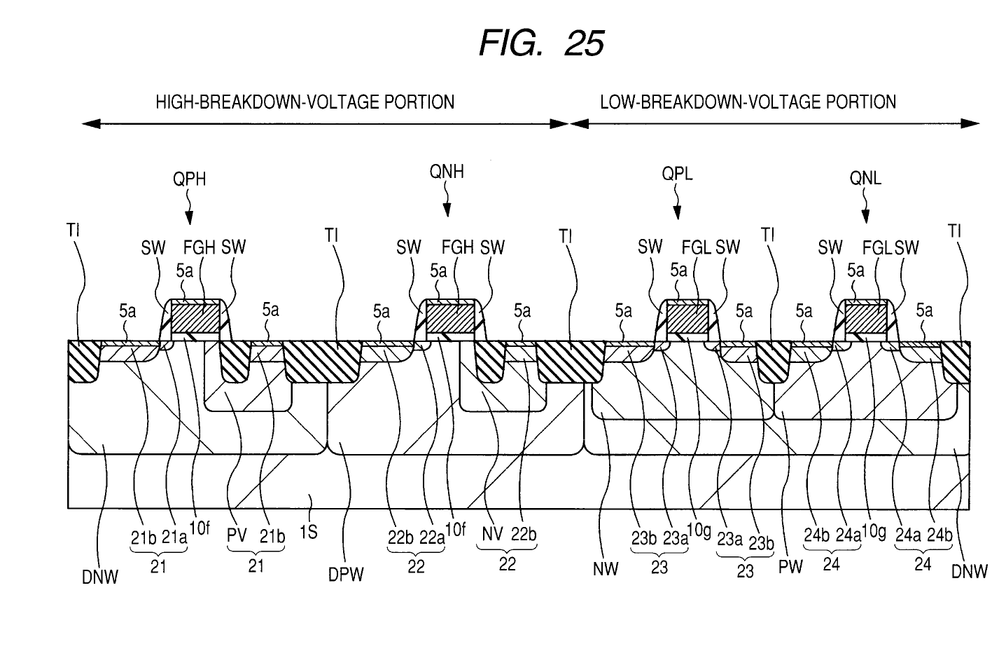

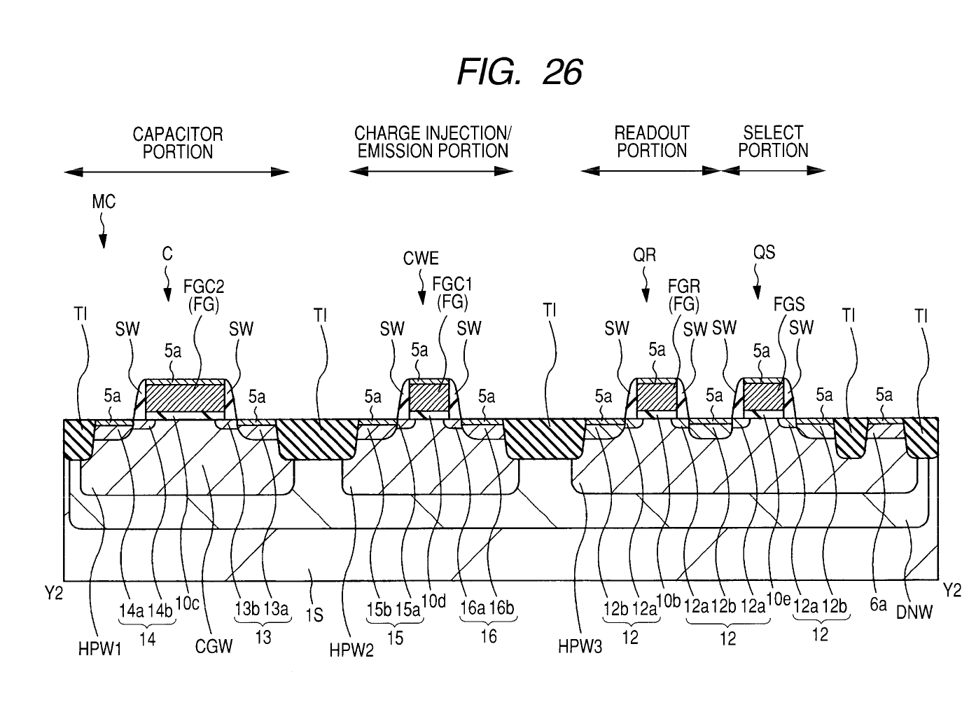

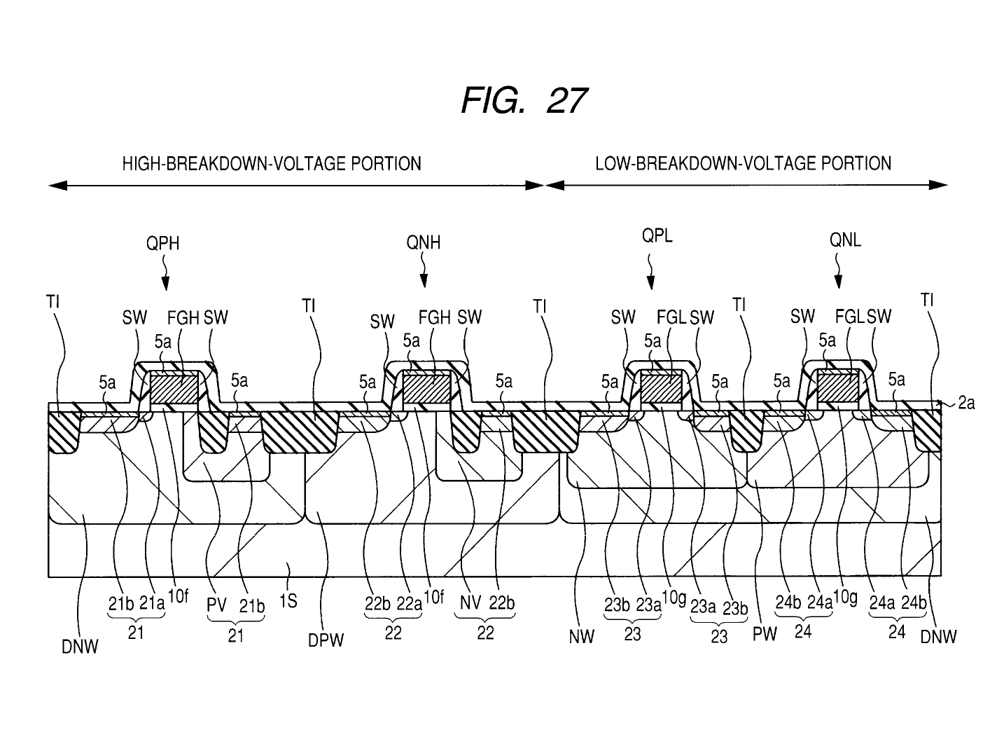

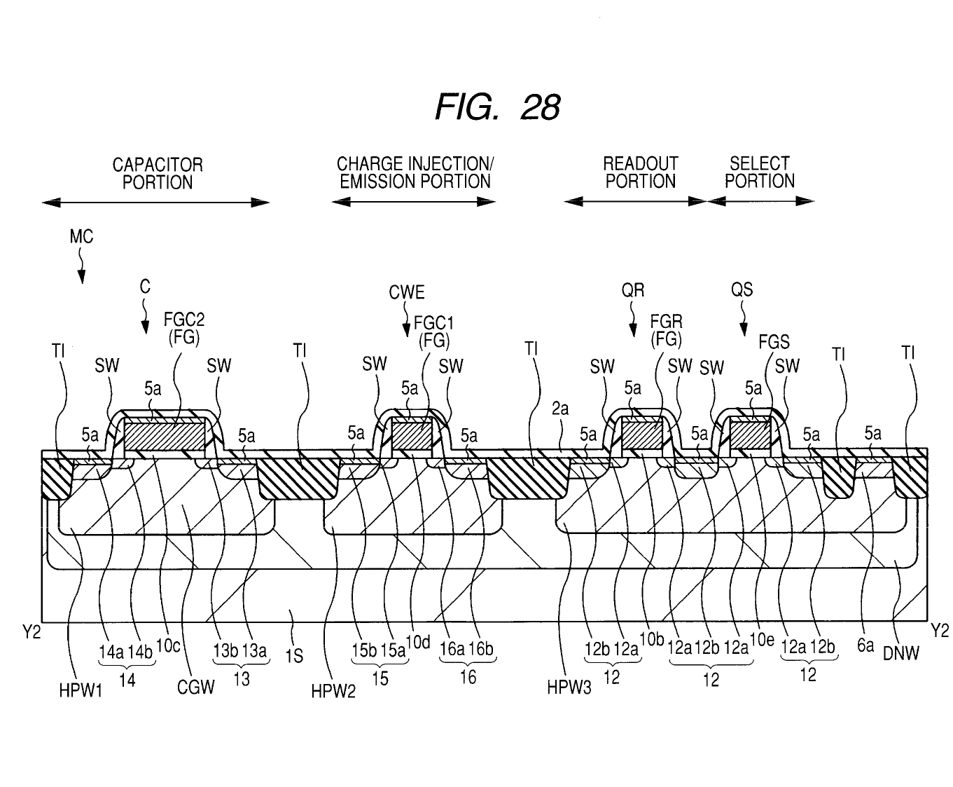

As illustrated in FIGS. 25 and 26, a silicide layer 5a is then selectively formed. As illustrated in FIGS. 27 and 28, an insulating film 2a made of, for example, silicon nitride film is deposited over the main surface of the substrate 1S (semiconductor wafer) by CVD or the like to cover the floating gate electrodes FG and gate electrodes FGH and FGL. In this stage, the insulating film 2a has been still deposited in both the memory cell array and LCD driver circuit region.

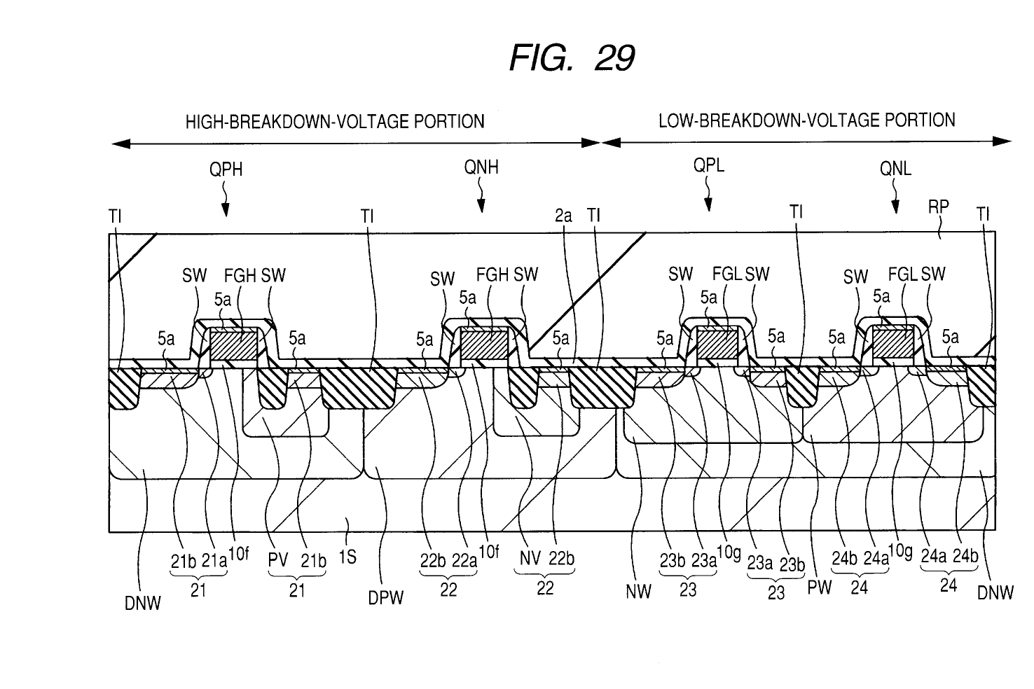

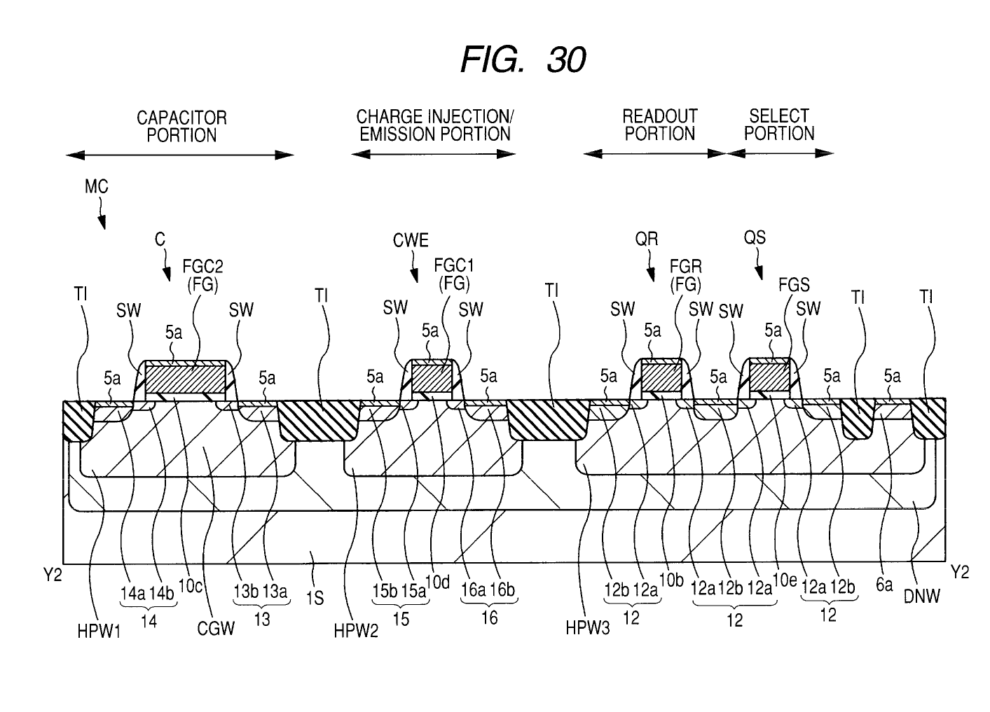

As illustrated in FIGS. 29 and 30, a resist pattern RP is formed over the insulating film 2a by lithography. This resist pattern RP has a pattern of covering regions other than memory cell array such as LCD driver circuit region and peripheral circuit region of the flash memory, while exposing the memory cell array from the resist pattern. With the resist pattern RP as an etching mask, the insulating film 2a is removed from the memory cell array. The resist pattern RP is then removed.

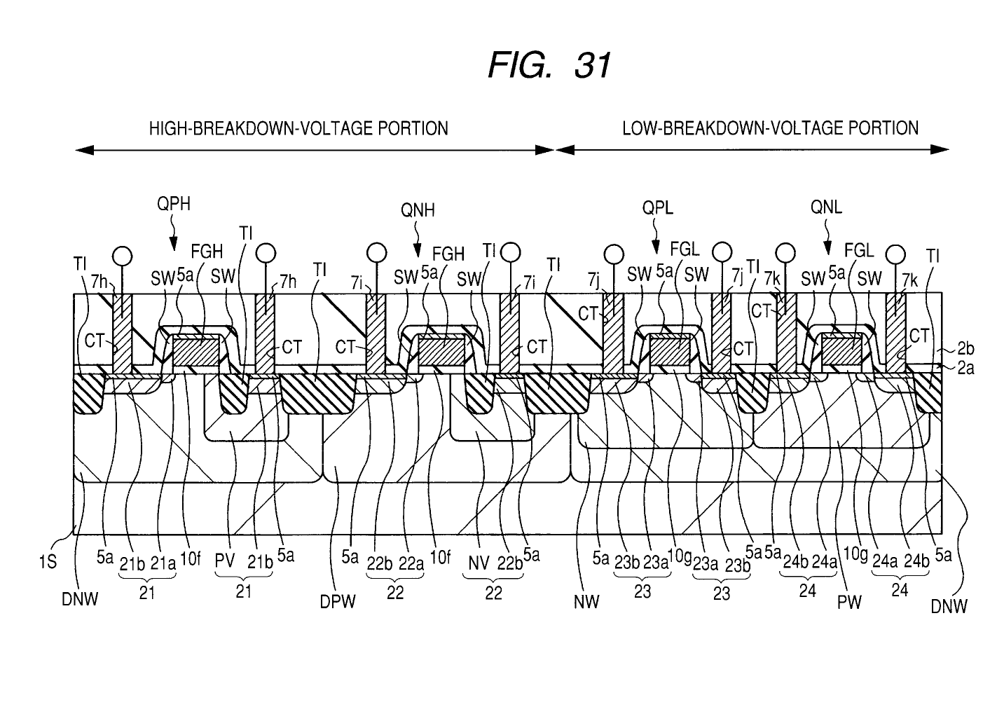

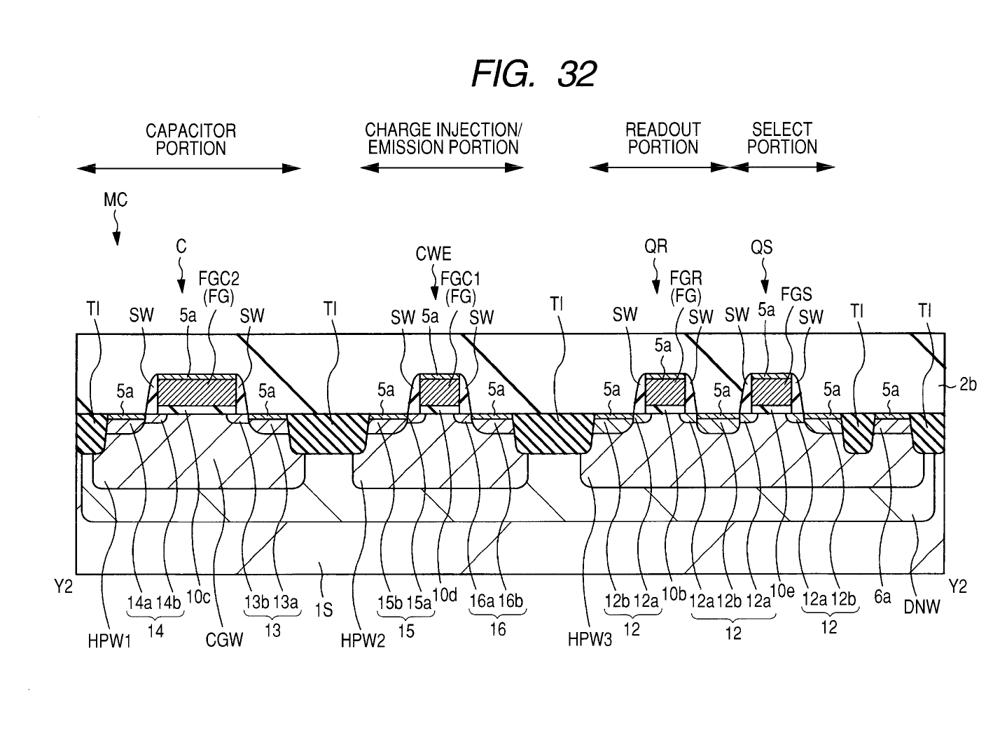

As illustrated in FIGS. 31 and 32, an interlayer insulating film 2b made of, for example, a silicon oxide film and thicker than the underlying insulating film 2a is deposited over the main surface of the substrate 1S by CVD or the like, followed by chemical mechanical polishing (CMP) of the upper surface of the interlayer insulating film 2b to planarize the upper surface of the interlayer insulating film 2b.

Contact holes CT are then formed in the interlayer insulating films 2b in the memory cell array and in the insulating films 2a and 2b in the LCD driver circuit region by lithography and etching. A conductor film made of, for example, tungsten (W) is deposited by CVD or the like over the main surface of the substrate 1S (semiconductor wafer) and then polished by CMP or the like to form conductor portions 7a and 7c to 7k in the contact holes CT.

The insulating film 2a is to function as an etching stopper during etching for the formation of the contact holes CT. Formation of the insulating film 2a enables size reduction of elements mainly in the main circuit region N. The semiconductor regions 12, 13, 14, 15 and 16 on the side of the memory cell array MR are wider than the semiconductor regions 23 and 24 in the main circuit region N. Owing to a sufficient space for the alignment of the contact holes CT, the insulating film 2a in the memory cell array MR is not necessary for forming the contact holes CT.

By the ordinarily employed metallization step, test step and assembly step, manufacture of the semiconductor device is completed.

According to the manufacturing method of the semiconductor device of Embodiment 1, constituents of the LCD driver circuit, that is, MIS•FET QPH, QNH, QPL and QNL, and constituents of the memory cell MC, that is, the capacitor portions C and CWE and MIS•FET QR and QS can be formed simultaneously so that the semiconductor device can be manufactured by simplified steps. This makes it possible to reduce the manufacturing time and cost of the semiconductor device.

### Embodiment 2

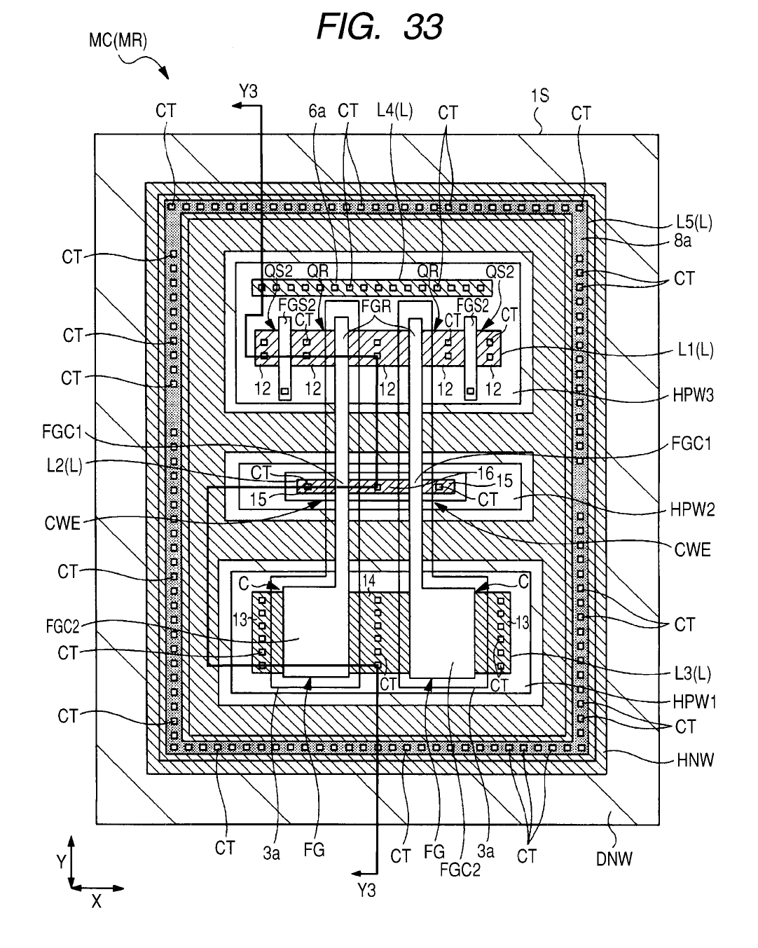

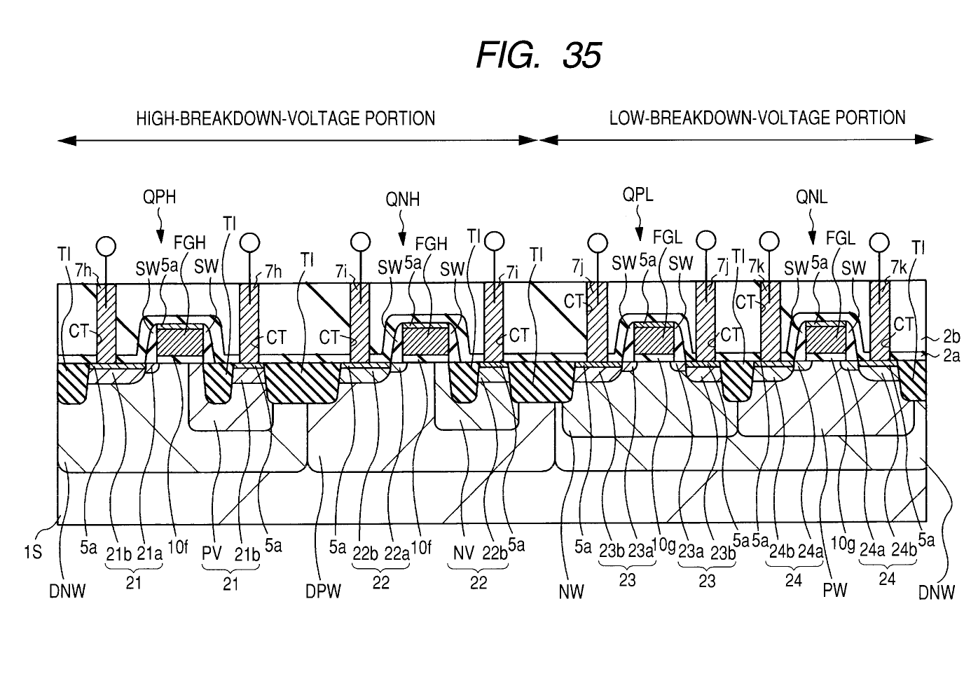

In Embodiment 2, specific examples of the semiconductor device having the constitution of FIG. 4 will be described based on FIGS. 33 and 35.

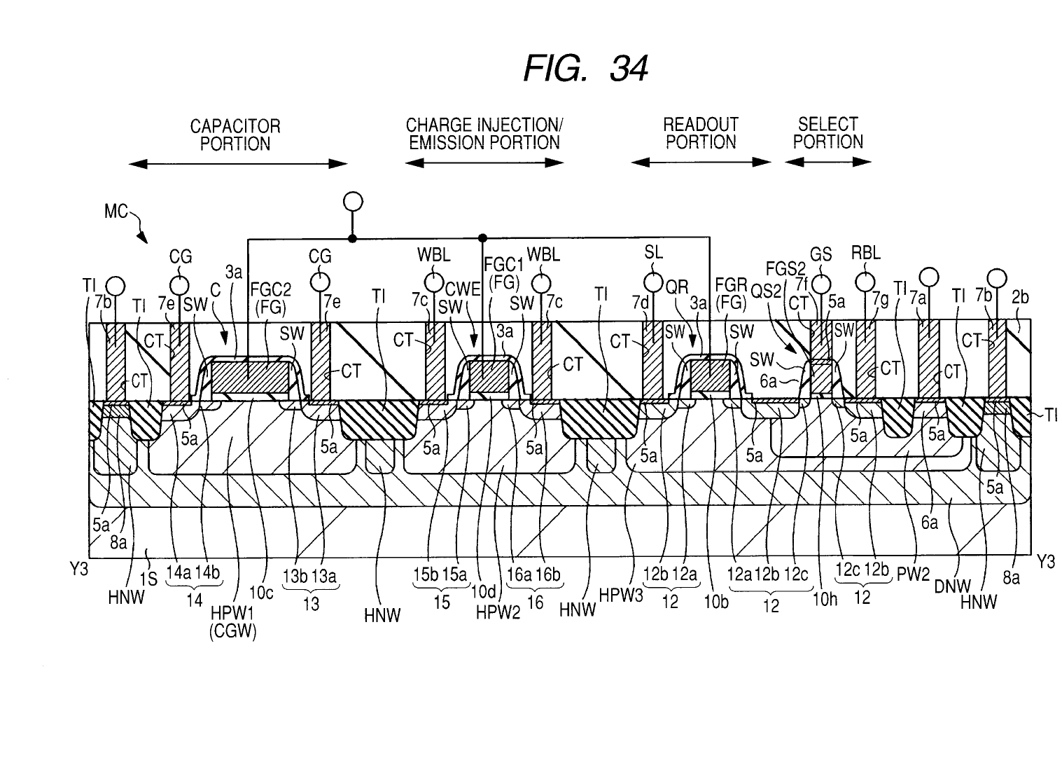

FIG. 33 is a plan view of one example of a memory cell MC of a flash memory in the semiconductor device of Embodiment 2; FIG. 34 is a cross-sectional view taken along a line Y3-Y3 of FIG. 33, and FIG. 35 is a fragmentary cross-sectional view of a main circuit region of the semiconductor device of Embodiment 2. In FIG. 33, some portions are hatched to facilitate understanding of the drawing.

In Embodiment 2, a cap insulating film (insulating film) 3a is formed in the memory cell array MR. The cap insulating film 3a is made of, for example, a silicon oxide film and is formed to cover therewith the upper surface of the floating gate electrode FG (such as capacitor electrode FGC1, FGC2 and gate electrode FGR), the entire surface of the sidewall S and a portion of the main surface of the substrate 1S around the sidewall SW.

The insulating film 2a is not formed in the memory cell array MR so that the cap insulating film 3a covers them while being in contact with the interlayer insulating film 2b. Also in this Embodiment 2, as illustrated in FIG. 35, the insulating film 2a is formed in circuit regions other than the flash memory such as LCD driver circuit region and peripheral circuit region of the flash memory and the insulating film 2a is not formed in the memory cell array MR of the flash memory as illustrated in FIG. 34. This makes it possible to suppress or prevent the leakage of electrons e from the floating gate electrode FG in the memory cell array MR of the flash memory without impairing miniaturization of elements in the circuit region other than the flash memory such as the LCD driver circuit region and peripheral circuit region of the flash memory. As a result, the resulting flash memory has improved data retention characteristics.

Formation of the cap insulating film 3a enables protection of the upper surface of the floating gate electrode FG by the cap insulating film 3a during removal of the insulating film 2a from the memory cell array MR, whereby the semiconductor device can be manufactured in an improved yield with higher reliability.

The cap insulating film 3a is formed by patterning prior to the formation step of the silicide layer 5a. Described specifically, after the steps illustrated in FIGS. 1 to 24 as explained in Embodiment 1, the cap insulating film 3a is deposited over the main surface of the substrate 1S, followed by patterning through lithography and etching. After that, the silicide layer 5a is formed and then, the insulating film 2a is deposited thereover and patterned as in Embodiment 1. Steps after that are omitted because they are similar to those of Embodiment 1.

The cap insulating film 3a can also be used also for the selective formation of the silicide layer 5a. For example, the cap insulating film 3a is formed over a resistor element (not illustrated) formed in another region of the main surface of the substrate 1S. This resistor element is made of, for example, a polycrystalline silicon film and is formed in one step with, for example, the above-described capacitor electrodes FGC1 and FGC2 and gate electrodes FGR, FGS and FGS2. Since a region with the silicide layer 5a on the resistor element and a region without the silicide layer 5a thereon can be formed selectively by forming the cap insulating film 3a on the resistor element, it is possible to set the resistance of the resistor element at a desired value. Thus, since the insulating film for selectively forming the silicide layer 5a and the cap insulating film 3a can be formed in one step, the formation of the cap insulating film 3a does not lead to an increase in the number of manufacturing steps of the semiconductor device.

For example, the cap insulating film 3a is formed so as to cover therewith channel-side portions of the upper surfaces of the p⁺ type semiconductor regions 13a and 15b, n⁺ type semiconductor regions 14a and 16b and n⁺ type semiconductor region 12b. Formation of the cap insulating film 3a in such a manner makes it possible to prevent the formation of the silicide layer 5a on the channel-side portions on the p⁺ type semiconductor regions 13a and 15b, n⁺ type semiconductor regions 14a and 16b and n⁺ type semiconductor region 12b. The silicide layer 5a is formed selectively in such a manner because of the following reason.

Described specifically, the growth of the silicide layer 5a into the lightly-doped p⁻ type semiconductor regions 13b and 15a, n⁻ type semiconductor regions 14b and 16a and n⁻ type semiconductor region 12a may cause a junction leakage current between the silicide layer 5a and substrate 1S. In particular, the possibility of occurrence of a junction leakage current increases when the lightly doped p⁻ type semiconductor regions 13b and 15a, n⁻ type semiconductor regions 14b and 16a and n⁻ type semiconductor region 12a are formed simultaneously (at an equal implantation concentration) with the semiconductor regions (particularly, lightly-doped semiconductor regions) for source and drain of the low-breakdown-voltage MIS•FET having an operating voltage of 1.5V.

In Embodiment 2, therefore, occurrence of a junction leakage can be suppressed or prevented by forming the cap insulating film 3a to isolate the silicide layer 5a from the lightly-doped p⁻ type semiconductor regions 13b and 15a and n⁻ type semiconductor region 12a.

The silicide layer 5a is formed after patterning of the cap insulating film 3a so that it is not formed on the upper surface of the floating gate electrode FG.

### Embodiment 3

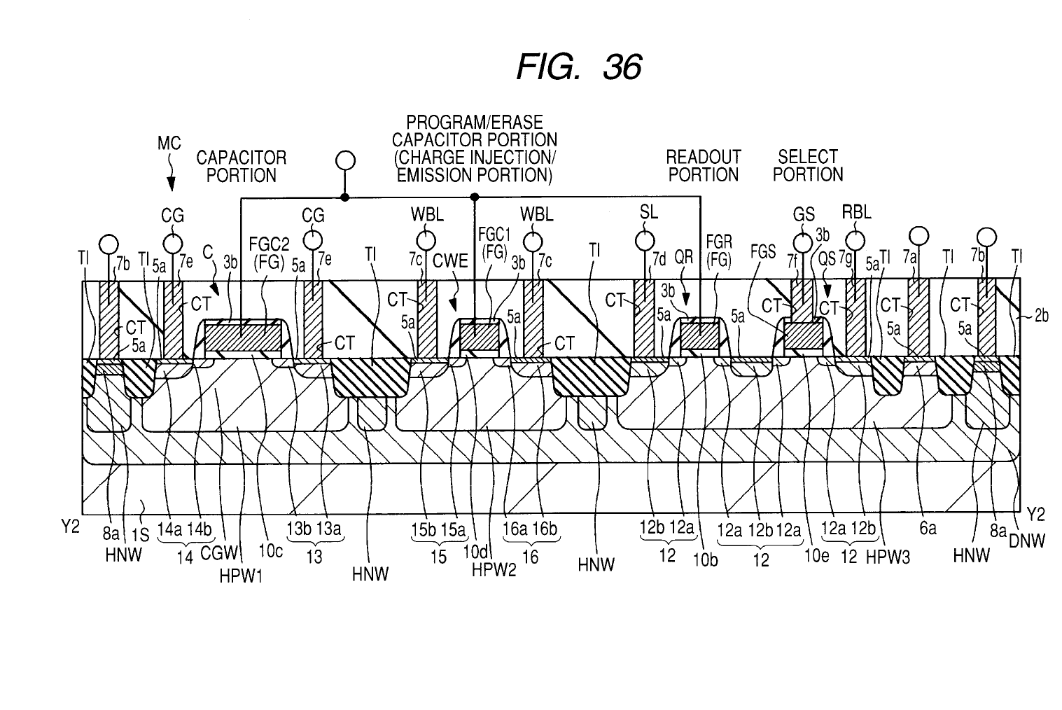

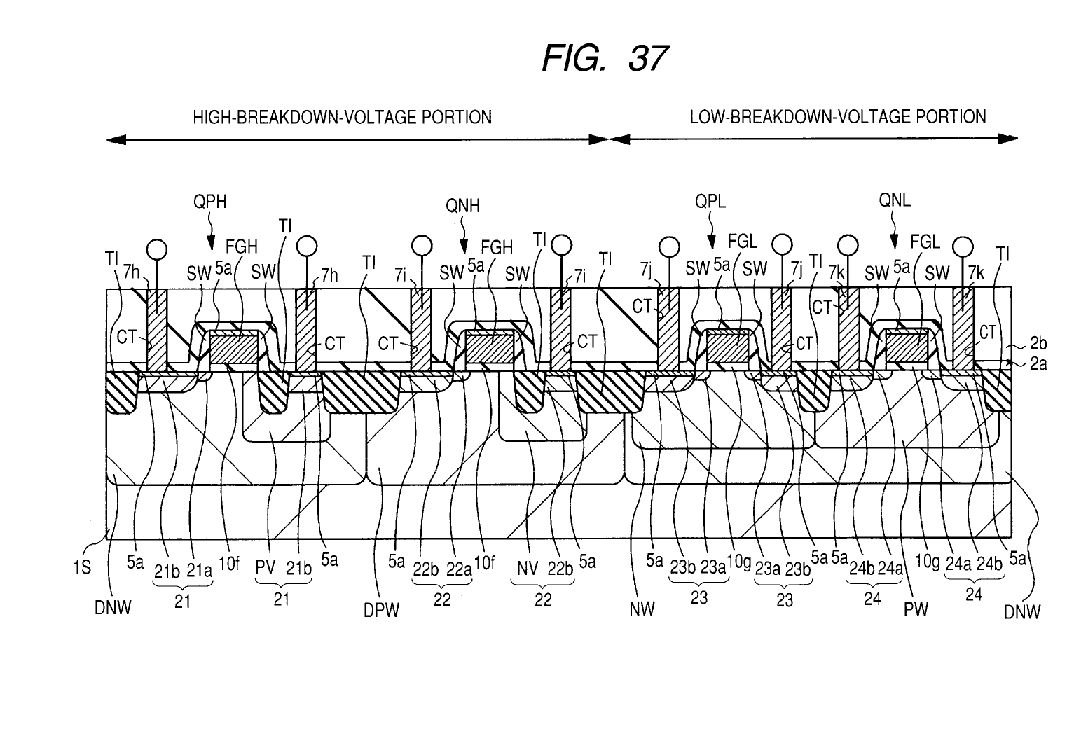

In Embodiment 3, a modification example of the cap insulating film 3a will be described based on FIGS. 36 and 37.

FIG. 36 is a cross-sectional view taken along a line Y2-Y2 of FIG. 11 and illustrates one example of a memory cell of a flash memory in a semiconductor device according to Embodiment 3; and FIG. 37 is a fragmentary cross-sectional view of a main circuit region of the semiconductor device of Embodiment 3. The plan view of the memory cell MC of the flash memory is similar to that of FIG. 11.

In Embodiment 3, a cap insulating film 3b, instead of the cap insulating film 3a, is formed in the memory cell array MR of the flash memory. This cap insulating film 3b is made of a silicon oxide film similar to the cap insulating film 3a, but the cap insulating film 3b covers therewith only the upper surface of the floating gate electrodes FG (such as capacitor electrodes FGC1 and FGC2, and gate electrode FGR) and the upper surface of the gate electrode FGS of the select MIS•FET QS.

The cap insulating film 3b is formed prior to the deposition of the insulating film 2a. This makes it possible to protect the upper surface of the floating gate electrodes FG and the upper surface of the gate electrode FGS of the select MIS•FET QS during removal of the insulating film 2a from the memory cell array MR. As a result, the yield and reliability of the semiconductor device can be improved.

### Embodiment 4

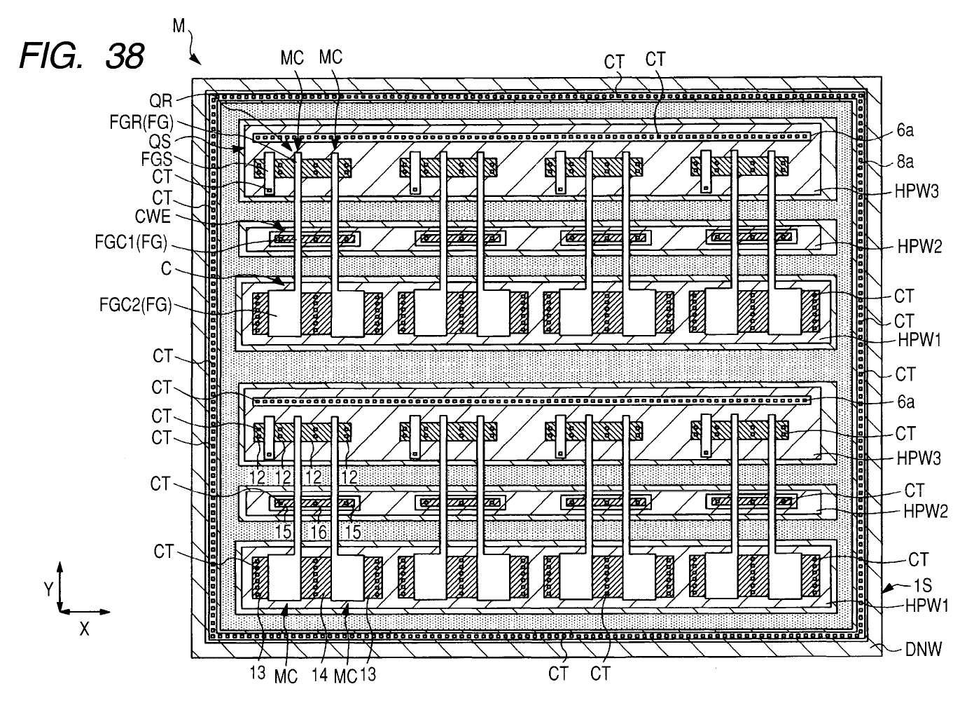

FIG. 38 is a fragmentary plan view of a memory cell array MR of a flash memory in a semiconductor device according to Embodiment 4. The cross-sectional constitution of the semiconductor device of Embodiment 4 is similar to that shown in Embodiments 1 to 3 so that illustration and description of it is omitted. The arrangement and constitution of the insulating film 2a and cap insulating films 3a and 3b are also similar to those described in Embodiments 1 to 3 so that description on them is omitted.

In Embodiment 4, in the memory cell array MR of the flash memory on the main surface (first main surface) of a substrate 1S constituting a semiconductor chip, a plurality of the above-described memory cells MC having, for example, a 8×2 bit structure are regularly arranged in the array (matrix) form.

P wells HPW1 to HPW3 extend in the second direction X. A capacitor portion C corresponding to a plurality of bits is placed in the p well HPW1. In the p well HPW2, a program•erase capacitor portion CWE corresponding to a plurality of bits is placed. In the p well HPW3, a data readout MIS•FET QR and select MIS•FET QS corresponding to a plurality of bits are arranged.

By employing such an array structure, a region occupied by the flash memory can be reduced so that the semiconductor device can have higher added value without increasing the size of a semiconductor chip.

### Embodiment 5

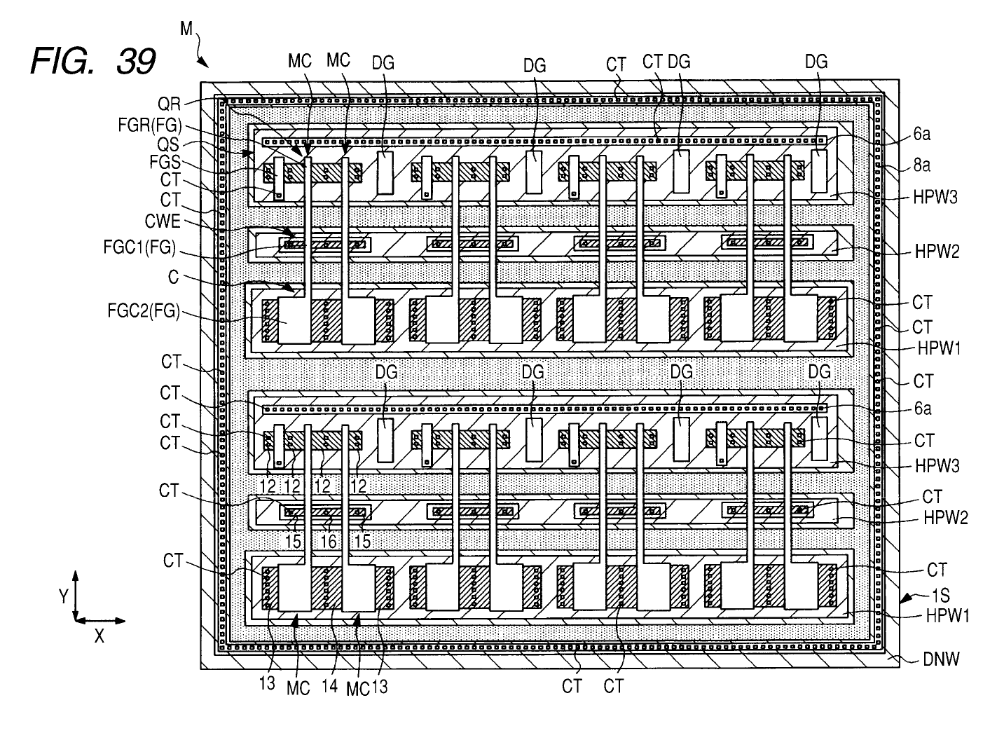

FIG. 39 is a plan view of a flash memory in a semiconductor device according to Embodiment 5.

In Embodiment 5, a dummy gate electrode DG is placed in a free-space region of the substrate 1S of the memory cell array MR of Embodiment 4. This dummy gate electrode DG is a pattern placed in consideration of the planarity of the interlayer insulating film 2b or repeated arrangement of patterns and is not electrically connected to another portion particularly.

Formation of the dummy gate electrode DG enables improvement of the planarity of the interlayer insulating film 2b, whereby interconnects and contact holes CT can be formed over and in the interlayer insulating film 2b, respectively, with improved precision.

The dummy gate electrode DG has a similar constitution to that of the floating gate electrode FG and they are formed in the same step. This makes it possible to locate the dummy gate electrode DG in the memory cell array MR without adding a new manufacturing step for it.

In Embodiment 5, description was made using the memory cell array MR of Embodiment 4 as an example, but similar effects are also available when it is applied to the memory cells MC of Embodiments 1 to 3.

### Embodiment 6

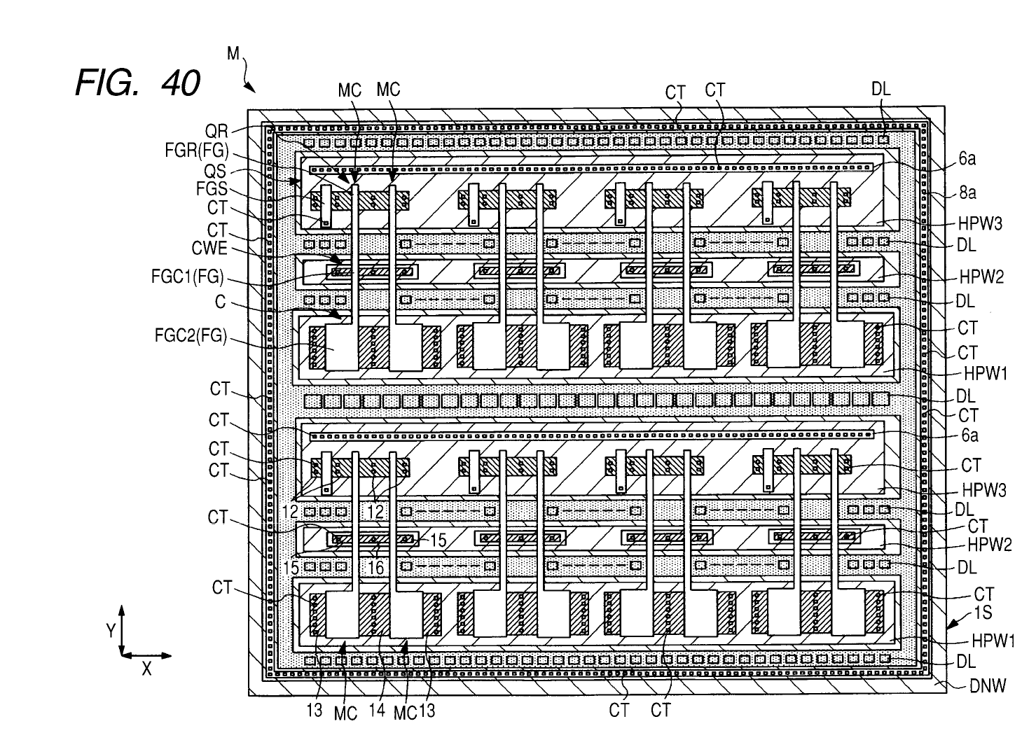

FIG. 40 is a plan view of a flash memory in a semiconductor device of Embodiment 6.

In Embodiment 6, a dummy active region DL is formed in a free-space region of the substrate 1S of the memory cell array MR of Embodiment 4. This dummy active region DL is formed in consideration of the planarity of the isolation portion TI and it is a region in which no semiconductor element is formed.

Formation of the dummy active region DL enables improvement of the planarity of the upper surface of the isolation portion TI, whereby an interlayer insulating film 2b or interconnect formed over the isolation portion TI can have improved planarity.

The dummy active region DL has a similar constitution to that of the active region L. The dummy active region DL and active region L are formed simultaneously so that the formation of the dummy active region DL does not increase the number of manufacturing steps of the semiconductor device.

A plurality of dummy active regions DL having a square plane are illustrated in the drawing. The shape of the dummy active region DL is not limited thereto, but may be, for example, rectangular or strip-like.

In Embodiment 6, description was made using the memory cell array MR of Embodiment 4 as an example, but similar effects are also available when it is applied to the memory cells MC of Embodiments 1 to 3.

The dummy active region DL of this Embodiment may be used in combination with the dummy gate electrode DG of Embodiment 5. Combined use enables further improvement of the planarity of the interlayer insulating film 2b.

The invention made by the present inventors was described specifically based on some embodiments. The invention is not limited to or by these embodiments. It is needless to say that various changes can be made without departing from the scope of the invention.

In the above-described embodiments, two memory cells MC constitute one bit (1 bit/2 cell mode). The constitution is not limited thereto, but one memory cell MC may constitute one bit (1 bit/1 cell mode). When two memory cells MC constitute one bit as in the above-described embodiments, one memory cell MC can retain data even if the other memory cell MC has a trouble and fails to retain data so that reliability of data retention can be improved further. When one memory cell MC constitutes one bit, on the other hand, miniaturization of a semiconductor device can be promoted because an area occupied by the memory cell per bit can be made smaller than that when two memory cells MC constitute one bit.

In the above description, the invention made by the present inventors is applied to a manufacturing method of a semiconductor device in the industrial field which constitutes the background of the invention. The invention can be applied not only to it but also to various methods, for example, a manufacturing method of a micromachine. In this case, simple information on the micromachine can be stored by forming the above-described flash memory on a semiconductor substrate having the micromachine formed thereon.

The present invention can be applied to the manufacturing industry of semiconductor devices having a nonvolatile memory.

1. A semiconductor device comprising:
a semiconductor substrate having a first main surface and a second main surface which are opposite to each other in the thickness direction; and
a first circuit region having a nonvolatile memory and a second circuit region having a circuit other than the nonvolatile memory, each formed over the first main surface of the semiconductor substrate,
the first circuit region comprising therein:
a first well of a first conductivity type formed over the first main surface of the semiconductor substrate;
a second well of a second conductivity type, which is opposite to the first conductivity type, enclosed in the first well;
a third well of the second conductivity type enclosed in the first well and extending along the second well while being electrically isolated from the second well;
a fourth well of the second conductivity type enclosed in the first well and extending along the second well while being electrically isolated from the second well and the third well; and
a nonvolatile memory cell two-dimensionally overlapping with the second well, the third well and the fourth well,
the nonvolatile memory cell comprising:
a floating gate electrode extending in a first direction so as to two-dimensionally overlap with the second well, the third well and the fourth well;
a data program/erase element formed at a first position where the floating gate electrode and the second well two-dimensionally overlap;
a data readout field effect transistor formed at a second position where the floating gate electrode and the third well two-dimensionally overlap; and
a capacitor element formed at a third position where the floating gate electrode and the fourth well two-dimensionally overlap;
the data program/erase element comprising:
a first electrode formed at the first position of the floating gate electrode;
an insulating film formed between the first electrode and the semiconductor substrate;
a pair of second-conductivity type semiconductor regions formed in the second well so as to sandwich the first electrode therebetween; and
the second well,
the data readout field effect transistor comprising:
a second electrode formed at the second position of the floating gate electrode;
an insulating film formed between the second electrode and the semiconductor substrate; and
a pair of first-conductivity-type semiconductor regions formed in the third well so as to sandwich the second electrode therebetween,
the capacitor element comprising:
a third electrode formed at the third position of the floating gate electrode;
an insulating film formed between the third electrode and the semiconductor substrate;
a pair of second-conductivity-type semiconductor regions formed in the fourth well so as to sandwich the third electrode therebetween; and
the fourth well,
wherein the second circuit region has therein a gate electrode,
wherein an oxygen-containing insulating film is deposited over the first main surface of the semiconductor substrate so as to cover the floating gate electrode and gate electrode, and
wherein a nitrogen-containing insulating film is formed between the oxygen-containing insulating film and the first main surface of the semiconductor substrate in the second circuit region so as to cover the gate electrode, while the nitrogen-containing insulating film is not formed between the oxygen-containing insulating film and the first main surface of the semiconductor substrate in the first circuit region.

2. A semiconductor device according to claim 1, wherein data rewriting in the data program/erase element is actualized by means of an FN tunneling current on the entire channel surface.

3. A semiconductor device according to claim 1, wherein the length of the third electrode in a second direction intersecting with the first direction is longer than the length of each of the first electrode and second electrode in the second direction.

4. A semiconductor device according to claim 1, wherein in the first circuit region, an oxygen-containing cap insulating film is formed between the oxygen-containing insulating film and the first main surface of the semiconductor substrate so as to cover the upper surface of the floating gate electrode.

5. A semiconductor device according to claim 4, wherein the oxygen-containing cap insulating film is formed to cover a portion of the first main surface of the semiconductor substrate so as to isolate the silicide layer formed over the first main surface of the semiconductor substrate from the side surface of the floating gate electrode.

6. A semiconductor device according to claim 5, wherein a low-breakdown-voltage field effect transistor to be driven at a first operating voltage and a high-breakdown-voltage field effect transistor driven at a second operating voltage higher than the first operating voltage are arranged in the second circuit region; and the semiconductor regions of the data write/erase element, data readout field effect transistor, and the capacitor element are formed simultaneously with the semiconductor regions of the low-breakdown-voltage field effect transistor.

7. A semiconductor device according to claim 1, wherein the oxygen-containing insulating film contains a silicon oxide film and the nitrogen-containing insulating film contains a silicon nitride film.

8. A semiconductor device comprising:
a semiconductor substrate having a first main surface and a second main surface which are opposite to each other along the thickness direction of the semiconductor substrate; and
a first circuit region having a nonvolatile memory and a second circuit region having a circuit other than the nonvolatile memory, each formed in the first main surface of the semiconductor substrate,
wherein a floating gate electrode of the nonvolatile memory is formed, via an insulating film, over the main surface of the semiconductor substrate in the first circuit region,
wherein a gate electrode is formed, via an insulating film, over the main surface of the semiconductor substrate in the second circuit region,
wherein an oxygen-containing insulating film is deposited over the first main surface of the semiconductor substrate so as to cover the floating gate electrode and the gate electrode, and
wherein a nitrogen-containing insulating film is formed between the oxygen-containing insulating film and the first main surface of the semiconductor substrate in the second circuit region so as to cover the gate electrode, while the nitrogen-containing insulating film is not formed between the oxygen-containing insulating film and the first main surface of the semiconductor substrate in the first circuit region.

9. A manufacturing method of a semiconductor device, comprising the steps of:
(a) preparing a semiconductor substrate having a first main surface and a second main surface which are opposite to each other in the thickness direction of the substrate;
(b) depositing a conductor film over the first main surface of the semiconductor substrate via an insulating film;
(c) patterning the conductor film to form a floating gate electrode for a nonvolatile memory in a first circuit region of the first main surface of the semiconductor substrate and simultaneously form a gate electrode in a second circuit region of the first main surface of the semiconductor substrate other than the first circuit region;
(d) depositing a nitrogen-containing insulating film over the first main surface of the semiconductor substrate so as to cover the floating gate electrode and the gate electrode;
(e) after the step (d), removing the nitrogen-containing insulating film by etching from the first circuit region and forming the nitrogen-containing insulating film pattern in the second circuit region;
(f) after the step (e), depositing an oxygen-containing insulating film over the first main surface of the semiconductor substrate so as to cover the nitrogen-containing insulating film pattern; and
(g) after the step (f), simultaneously forming a connecting hole in the oxygen-containing insulating film in the first circuit region and the second circuit region.

10. A manufacturing method of a semiconductor device according to claim 9,
wherein the first circuit region comprises therein:
a first well of a first conductivity type formed over the first main surface of the semiconductor substrate;
a second well of a second conductivity type, which is opposite to the first conductivity type, enclosed in the first well;
a third well of the second conductivity type enclosed in the first well and extending along the second well while being electrically isolated from the second well;
a fourth well of the second conductivity type enclosed in the first well and extending along the second well while being electrically isolated from the second well and the third well; and
a nonvolatile memory cell two-dimensionally overlapping with the second well, the third well and the fourth well,
wherein the nonvolatile memory cell comprises:
a floating gate electrode extending in a first direction so as to two-dimensionally overlap with the second well, the third well and the fourth well;
a data program/erase element formed at a first position where the floating gate electrode and the second well two-dimensionally overlap;
a data readout field effect transistor formed at a second position where the floating gate electrode and the third well two-dimensionally overlap; and
a capacitor element formed at a third position where the floating gate electrode and the fourth well two-dimensionally overlap,
wherein the data program/erase element comprises:
a first electrode formed at the first position of the floating gate electrode;
an insulating film formed between the first electrode and the semiconductor substrate;
a pair of second-conductivity type semiconductor regions formed in the second well so as to sandwich the first electrode therebetween; and
the second well,
the data readout field effect transistor comprises:
a second electrode formed at the second position of the floating gate electrode;
an insulating film formed between the second electrode and the semiconductor substrate; and
a pair of first-conductivity-type semiconductor regions formed in the third well so as to sandwich the second electrode therebetween, and
wherein the capacitor element comprises:
a third electrode formed at the third position of the floating gate electrode;
an insulating film formed between the third electrode and the semiconductor substrate;
a pair of second-conductivity-type semiconductor regions formed in the fourth well so as to sandwich the third electrode therebetween; and
the fourth well.

11. A manufacturing method of a semiconductor device according to claim 10, further comprising, after the step (c) but before the step (d), the step of forming an oxygen-containing cap insulating film so as to cover the upper surface of the floating gate electrode.

12. A manufacturing method of a semiconductor device according to claim 11, further comprising, after the formation of the oxygen-containing cap insulating film, the step of forming a silicide layer over the first main surface of the semiconductor substrate,
wherein in the formation step of the oxygen-containing cap insulating film, the oxygen-containing cap insulating film is formed so that a portion of the oxygen-containing cap insulating film covers a portion of the first main surface of the semiconductor substrate so as to isolate the silicide layer from the side surface of the floating gate electrode.

13. A manufacturing method of a semiconductor device according to claim 10,
wherein a low-breakdown-voltage field effect transistor to be driven at a first operating voltage and a high-breakdown-voltage field effect transistor to be driven at a second operating voltage higher than the first operating voltage are arranged in the second circuit region, and
wherein the semiconductor regions of the data write/erase element, data readout field effect transistor and capacitor element are formed simultaneously with the semiconductor region of the low-breakdown-voltage field effect transistor.

14. A manufacturing method of a semiconductor device according to claim 9, wherein the nitrogen-containing insulating film has a silicon nitride film and the oxygen-containing insulating film has a silicon oxide film.
